(19) United States
(12) Patent Application Publication
(10) Pub. No.: US 2026/0007012 A1
(43) Pub. Date: Jan. 1, 2026

(54) DISPLAY DEVICE

(71) Applicant: Samsung Display Co., LTD., Yongin-si (KR)

(72) Inventors: Jun Geun PARK, Yongin-si (KR); Jae Hyuk YU, Yongin-si (KR); Yu Jin LEE, Yongin-si (KR)

(21) Appl. No.: 19/054,680

(22) Filed: Feb. 14, 2025

(30) Foreign Application Priority Data
Jun. 27, 2024 (KR) 10-2024-0084600

(51) Int. Cl. H10K 59/131; H10K 59/124

(52) U.S. Cl. CPC H10K 59/131; H10K 59/124

(57) ABSTRACT

A display device includes a substrate having a display area and a pad area, a first insulating layer on the pad area of the substrate, a pad including first to fourth conductive layers sequentially stacked on the first insulating layer, a second insulating layer between the first and the second conductive layers and including first contact portions where the first and the second conductive layers are in contact, a third insulating layer between the third and the fourth conductive layers and including second contact portions where the third conductive layer and the fourth conductive layer are in contact, a driving circuit on the pad and including a bump, and an anisotropic conductive film between the pad and the driving circuit and including a plurality of conductive balls, wherein the first contact portions overlap the second contact portions and are spaced from each other along a longitudinal direction of the pad.

### CROSS-REFERENCE TO RELATED APPLICATION

The present application claims priority to and the benefit of Korean Patent Application No. 10-2024-0084600, filed on Jun. 27, 2024, in the Korean Intellectual Property Office, the entire disclosure of which is incorporated herein by reference.

### BACKGROUND

### 1. Field

Embodiments of the present disclosure relate to a display device.

### 2. Description of the Related Art

The importance of display devices has been gradually increasing with the continual development of multimedia. In response, various display devices, such as liquid crystal display devices and/or light-emitting display devices, have been developed.

A display device includes a display panel including a display area where pixels are arranged and a pad area where pads are arranged. The pads may be exposed on a substrate of the display panel and connected to a driving circuit or circuit board provided as an integrated circuit chip (IC), thereby transmitting input and output signals of the display panel.

The above information disclosed in this Background section is intended to enhance understanding of the background of the disclosure and may contain information that does not constitute prior art.

### SUMMARY

Aspects of one or more embodiments of the present disclosure are directed toward a display device capable of improving contact defects and to improving the reliability of a pad area. For example, one or more embodiments of the present disclosure are directed toward a display device designed to improve contact defects, which are issues at the electrical connection points, and enhance the reliability of the pad area.

However, aspects of the present disclosure are not restricted to those set forth herein. Additional aspects will be set forth in part in the description which follows and, in part, will be apparent from the description, or may be learned by practice of the presented embodiments of the disclosure.

According to one or more embodiments of the present disclosure, a display device includes a substrate including (having) a display area and a pad area, a first insulating layer arranged on the pad area of the substrate, a pad including a first conductive layer, a second conductive layer, a third conductive layer, and a fourth conductive layer sequentially stacked on the first insulating layer, a second insulating layer arranged between the first conductive layer and the second conductive layer and including first contact portions where the first conductive layer and the second conductive layer are in contact, a third insulating layer arranged between the third conductive layer and the fourth conductive layer and including second contact portions where the third conductive layer and the fourth conductive layer are in contact, a driving circuit arranged on the pad and including a bump, and an anisotropic conductive film arranged between the pad and the driving circuit and including a plurality of conductive balls, wherein the first contact portions overlap the second contact portions and are spaced and/or apart (e.g., spaced apart or separated) from each other along a longitudinal direction of the pad.

In one or more embodiments, the second conductive layer and the third conductive layer may be in contact with each other on the first contact portions, so that the first conductive layer, the second conductive layer, the third conductive layer, and the fourth conductive layer are electrically connected.

In one or more embodiments, at least one of the plurality of conductive balls may be arranged on a portion (e.g., an area) of the second contact portions that does not overlap the first contact portions and may be in contact with the pad and the bump.

In one or more embodiments, at least one of the plurality of conductive balls may overlap the first contact portions and may not be in contact with the pad or the bump.

In one or more embodiments, a total area of the first contact portions may be 2% to 45% of an area of the pad.

In one or more embodiments, the area of the pad may be an area of the fourth conductive layer.

In one or more embodiments, a maximum distance between the pad and the bump in an area where the first contact portions and the second contact portions overlap may be greater than a maximum distance between the pad and the bump in an area where the first contact portions and the second contact portions do not overlap.

In one or more embodiments, the first contact portions may at least partially overlap the bump.

In one or more embodiments, the first contact portions may completely overlap the bump.

In one or more embodiments, at least one of the first contact portions may not overlap the bump.

In one or more embodiments, the bump includes a groove-shaped dimple arranged on one surface facing (e.g., opposite to) the pad, and the dimple may overlap at least one of the first contact portions.

According to one or more embodiments of the present disclosure, a display device includes a substrate including (having) a display area and a pad area, a first insulating layer arranged on the pad area of the substrate, a pad including a first conductive layer, a second conductive layer, a third conductive layer, and a fourth conductive layer sequentially stacked on the first insulating layer, a second insulating layer arranged between the first conductive layer and the second conductive layer and including first contact portions where the first conductive layer and the second conductive layer are in contact, a third insulating layer arranged between the third conductive layer and the fourth conductive layer and including second contact portions where the third conductive layer and the fourth conductive layer are in contact, a driving circuit arranged on the pad and including a bump having a dimple on one surface facing (e.g., opposite to) the pad, and an anisotropic conductive film arranged between the pad and the driving circuit and including a plurality of conductive balls, wherein in an area of the second contact portions that does not overlap the first contact portions, the pad and the bump are each in contact with the plurality of conductive balls.

In one or more embodiments, at least one of the plurality of conductive balls may overlap the first contact portions and may not be in contact with the pad or the bump.

In one or more embodiments, a total area of the first contact portions may be 2% to 45% of an area of the pad.

In one or more embodiments, the area of the pad may be an area of the fourth conductive layer.

In one or more embodiments, the first contact portions may at least partially overlap the bump.

In one or more embodiments, the first contact portions may completely overlap the bump.

In one or more embodiments, at least one of the first contact portions may not overlap the bump.

In one or more embodiments, the display device further may include a transistor arranged on the display area, at least one planarization layer arranged on the transistor and including an organic insulating material, a connection electrode arranged on the at least one planarization layer, and sensor electrodes arranged on the connection electrode, wherein the transistor may include an active layer arranged between the substrate and the first insulating layer, a gate electrode arranged on the first insulating layer, and a source electrode or a drain electrode arranged on the second insulating layer. For example, the transistor includes an active layer between the substrate and the first insulating layer, a gate electrode on the first insulating layer, a source electrode, and a drain electrode, with at least one of the source electrode or the drain electrode on the second insulating layer.

In one or more embodiments, the first conductive layer may include the same material as the gate electrode, the second conductive layer may include the same material as the source electrode or the drain electrode, the third conductive layer may include the same material as the connection electrode, and the fourth conductive layer may include the same material as the sensor electrodes.

According to one or more embodiments of the present disclosure, a an electronic device include a display device including a substrate having a display area and a pad area, a first insulating layer arranged on the pad area of the substrate, a pad including a first conductive layer, a second conductive layer, a third conductive layer, and a fourth conductive layer sequentially stacked on the first insulating layer, a second insulating layer arranged between the first conductive layer and the second conductive layer and including first contact portions where the first conductive layer and the second conductive layer are in contact, a third insulating layer arranged between the third conductive layer and the fourth conductive layer and including second contact portions where the third conductive layer and the fourth conductive layer are in contact, a driving circuit arranged on the pad and including a bump, and an anisotropic conductive film arranged between the pad and the driving circuit and including a plurality of conductive balls, wherein the first contact portions overlap the second contact portions and are spaced and/or apart (e.g., spaced apart or separated) from each other along a longitudinal direction of the pad.

The display device according to one or more embodiments may increase an effective contact area where a bump having a dimple and a pad may be in contact with a conductive ball by configuring a plurality of first contact portions of the pad and arranging the first contact portions to overlap the bump. By including more than one first contact portion, second contact portions to connect the driving circuit to the pad may have a greater area to effectively contact the bump of the driving circuit, thus increasing the effective contact area. Accordingly, contact defects between the pad and the bump of the driving circuit may be prevented or reduced and reliability of the pad may be improved.

However, the effects of the embodiments are not restricted to the ones set forth herein. The above and other effects of one or more embodiments will become more apparent to one of ordinary skill in the art to which the embodiments pertain by referencing the claims.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a plan view illustrating a display device according to one or more embodiments of the present disclosure;

FIG. 2 is a plan view illustrating a display panel of FIG. 1, according to one or more embodiments of the present disclosure;

FIG. 3 is a cross-sectional view of a display area of the display panel taken along the line X1-X1′ of FIG. 2, according to one or more embodiments of the present disclosure;

FIG. 4 is a plan view illustrating pads in a first pad area according to one or more embodiments of the present disclosure;

FIG. 5 is a plan view illustrating a pad area of the display panel at the area A1 of FIG. 4, according to one or more embodiments of the present disclosure;

FIG. 6 is a cross-sectional view taken along the line X2-X2′ of FIG. 5, according to one or more embodiments of the present disclosure;

FIG. 7 is a cross-sectional view taken along the line X3-X3′ of FIG. 5, according to one or more embodiments of the present disclosure;

FIG. 8 is a cross-sectional view taken along the line X4-X4′ of FIG. 5, according to one or more embodiments of the present disclosure;

FIG. 9 is a cross-sectional view schematically illustrating a bump of a driving circuit, according to one or more embodiments of the present disclosure;

FIGS. 10 and 11 are cross-sectional views illustrating a method of manufacturing the bump of the driving circuit for each step (e.g., act or task) of the process, according to one or more embodiments of the present disclosure;

FIG. 12 is a plan view illustrating a pad area of the display panel, according to one or more embodiments of the present disclosure;

FIG. 13 is a cross-sectional view taken along the line X5-X5′ of FIG. 12, according to one or more embodiments of the present disclosure;

FIG. 14 is a cross-sectional view taken along the line X6-X6′ of FIG. 12, according to one or more embodiments of the present disclosure;

FIG. 15 is a cross-sectional view taken along the line X7-X7′ of FIG. 12, according to one or more embodiments of the present disclosure;

FIG. 16 is a plan view illustrating a first pad area of a display panel according to a comparative example;

FIG. 17 is a schematic view illustrating a first pad area of a display panel according to a comparative example;

FIG. 18 is a schematic view illustrating a first pad area of a display panel according to one or more embodiments of the present disclosure;

FIG. 19 is a plan view illustrating a pad of a display panel according to one or more embodiments of the present disclosure;

FIG. 20 is a cross-sectional view taken along the line X8-X8′ of FIG. 19, according to one or more embodiments of the present disclosure;

FIG. 21 is a plan view illustrating a pad of a display panel according to one or more embodiments of the present disclosure;

FIG. 22 is a cross-sectional view taken along the line X9-X9′ of FIG. 21, according to one or more embodiments of the present disclosure; and

FIG. 23 is a chart illustrating the area and effective contact area of first contact portions for each pad structure according to a comparative example and example embodiments.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or the like include or support the terms “consisting of” and “consisting essentially of,” indicating the presence of stated features, integers, steps, operations, elements, and/or components, with or without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction (DR1) and the second direction (DR2). This refers to that in a plan view, the arrangement of sub-pixels, pads, and other components as they are laid out on the substrate can be seen, without any perspective distortion.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

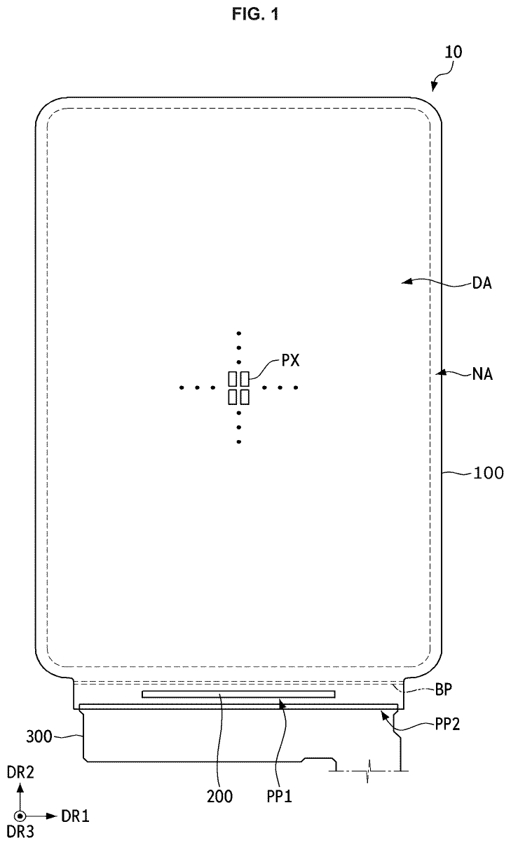

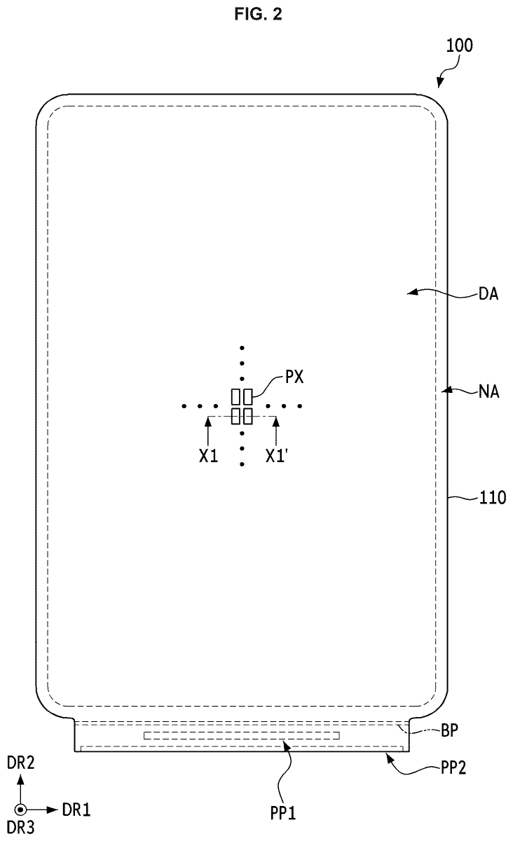

FIG. 1 is a plan view illustrating a display device according to one or more embodiments of the present disclosure. FIG. 2 is a plan view illustrating a display panel of FIG. 1, according to one or more embodiments of the present disclosure.

Referring to FIGS. 1 and 2, a display device 10 may include a display panel 100, and a driving circuit 200 and a circuit board 300 connected to the display panel 100. The display panel 100 may form a display unit to display an image. The driving circuit 200 and the circuit board 300 may form a driver to generate and/or transmit driving signals of the display panel 100.

The display panel 100 may include a display area DA where pixels PX are arranged and an image is displayed. In one or more embodiments, the display panel 100 may further include a touch sensor including sensor electrodes arranged in at least a portion of the display area DA. The display device 10 may sense a touch input in an area where the touch sensor is provided.

The display device 10 according to one or more embodiments of the present disclosure may be applied to portable electronic devices such as mobile phones, smartphones, tablet personal computers (PCs), mobile communication terminals, electronic notebooks, electronic books, portable multimedia players (PMPs), navigation devices, and/or ultra-mobile PCs (UMPCs). Alternatively, the display device 10 according to one or more embodiments may be applied as a display unit of a television, a notebook computer, a monitor, a billboard, and/or an Internet of things (IoT) device. Alternatively, the display device 10 according to one or more embodiments may be applied to wearable devices such as smart watches, watch phones, glasses-type (kind) displays, and/or head-mounted displays (HMDs). Alternatively, the display device 10 according to one or more embodiments may be applied to a car display, such as a display in a dashboard of a vehicle, a center fascia of a vehicle, a center information display (CID) arranged on a dashboard of a vehicle, a room mirror display replacing side mirrors of a vehicle, and/or a display arranged on the back of a front seat as an entertainment for rear-seat passengers of a vehicle.

As illustrated in FIG. 2, the display panel 100 may include a substrate 110 forming a base surface and pixels PX arranged on the substrate 110. The pixels PX may be arranged and/or formed in a display area DA on the substrate 110.

In one or more embodiments, the display area DA may include a short side in a first direction DR1 and a long side in a second direction DR2 and may be formed to be planar having a substantially rectangular shape. A corner portion where the long side and the short side of the display area DA meet may be rounded or formed at a right angle. The shape of the display area DA may be variously changed depending on the embodiment. For example, the display area DA may be formed in a polygonal shape other than a square shape, a circular shape, or an elliptical shape. In FIGS. 1 and 2, the first direction DR1 and the second direction DR2 may be a horizontal direction (or row direction) and a vertical direction (or column direction) of the display panel 100, respectively. A third direction DR3 may be a direction that intersects a main surface of the display panel 100 defined by the first direction DR1 and the second direction DR2. For example, the third direction DR3 may be a thickness direction of the display panel 100 (or the substrate 110).

In one or more embodiments, the display panel 100 may be substantially flat on a plane (e.g., in a plan view) defined by the first direction DR1 and the second direction DR2 and may have a set or predetermined thickness (or height) in the third direction DR3. In one or more embodiments, the display panel 100 may include a curved portion in at least one portion, including an edge area. In one or more embodiments, the display panel 100 may be flexibly formed to be curved, bent, folded, or rolled.

The display panel 100 may further include a non-display area NA positioned around the display area DA. The non-display area NA is the remaining area of the entire area of the display panel 100 excluding the display area DA, and may be around (e.g., surround) the display area DA.

The display panel 100 may further include pads arranged in the non-display area NA on the substrate 110. The pads may be positioned in at least one pad area positioned in the non-display area NA. For example, the non-display area NA may include a first pad area PP1 (also referred to as a “first pad portion”) and a second pad area PP2 (also referred to as a “second pad portion”), and a plurality of pads may be arranged and/or formed in each of the first pad area PP1 and the second pad area PP2.

The pads positioned in the first pad area PP1 may be electrically connected to the driving circuit 200. The pads positioned in the second pad area PP2 may be electrically connected to the circuit board 300.

In one or more embodiments, the display panel 100 may include a bending area BP (also referred to as a “bending portion”). In one or more embodiments, the bending area BP may be positioned across the display panel 100 in the first direction DR1 between the display area DA and the second pad area PP2.

The display panel 100 may be bent in the bending area BP. For example, if (e.g., when) the display panel 100 is a top emission type (kind), the display panel 100 may be bent in the bending area BP so that the first pad area PP1, the second pad area PP2, the driving circuit 200, and the circuit board 300 positioned farther from the display area DA than the bending area BP are positioned on a rear surface of the display panel 100. Accordingly, a width of a bezel area may be reduced or minimized. Whether the display panel 100 is bent and/or the position of the bending area BP may be variously changed depending on the embodiment. For example, the bending area BP may also be positioned across the display area DA and/or the non-display area NA.

The driving circuit 200 may include a data driving circuit for supplying data signals to the pixels PX. In one or more embodiments, the driving circuit 200 may be provided as an integrated circuit chip and mounted on the first pad area PP1. The driving circuit 200 may be electrically connected to the display panel 100 through the pads positioned in the first pad area PP1.

The circuit board 300 may be arranged on the second pad area PP2. For example, the circuit board 300 may be bonded to the pads positioned in the second pad area PP2, and may supply or transfer power voltages and driving signals for driving the display panel 100 and/or the driving circuit 200 to the pads positioned in the second pad area PP2. In one or more embodiments in which the display panel 100 further includes a touch sensor, the circuit board 300 may supply driving signals for driving at least some sensor electrodes (e.g., driving electrodes) to the display panel 100, and may receive sensing signals output from at least some sensor electrodes (e.g., sensing electrodes). The circuit board 300 may be a flexible film such as a flexible printed circuit board (FPCB), a printed circuit board (PCB), or a chip on film (COF), but the present disclosure is not limited thereto.

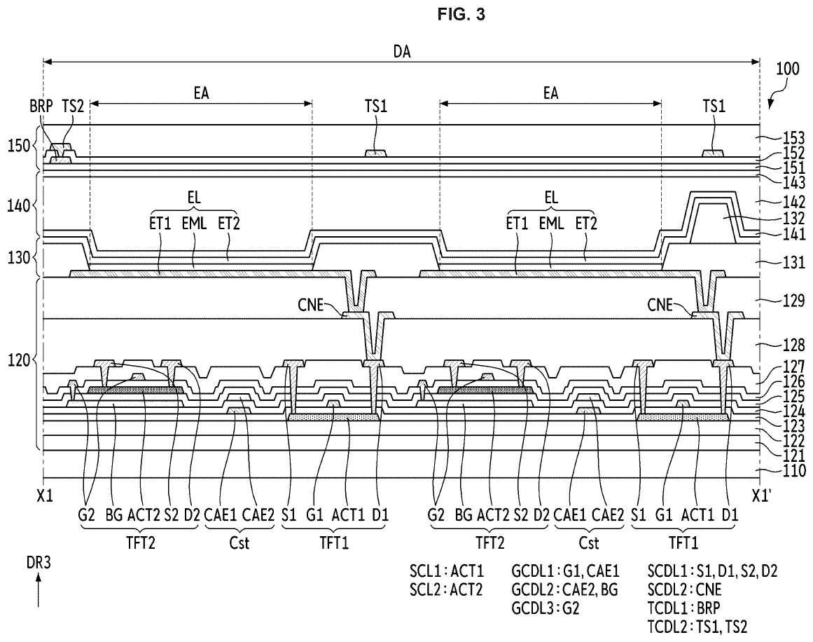

FIG. 3 is a cross-sectional view of a display area of the display panel according to one or more embodiments of the present disclosure. For example, FIG. 3 illustrates an example of a cross section of a portion of the display area DA corresponding to line X1 to X1′ in FIG. 2, according to one or more embodiments of the present disclosure.

FIG. 3 illustrates a light emitting display panel including a light emitting element EL (e.g., an organic light emitting diode), as an example of the display panel 100 to which one or more embodiments may be applied. However, the structure and type (kind) of the display panel 100 and the display device 10 including the same according to the present disclosure is not limited thereto. For example, the display device 10 may be a light emitting display device such as an organic light emitting display device including an organic light emitting diode, a quantum dot light emitting display device including a quantum dot light emitting layer, an inorganic light emitting display device including an inorganic semiconductor, and a light emitting display device using a ultra-small light emitting diode such as a micro or nano light emitting diode (LED). In one or more embodiments, the display device 10 may also be a type (kind) of display device other than the light emitting display device.

Referring to FIG. 3 in addition to FIGS. 1 and 2, the display panel 100 may include a substrate 110, a circuit layer 120, a light emitting element layer 130, and an encapsulation layer 140 arranged on the substrate 110. In one or more embodiments, the circuit layer 120, the light emitting element layer 130, and the encapsulation layer 140 may be sequentially arranged and/or stacked on the substrate 110 along the third direction DR3. In describing one or more embodiments, the circuit layer 120 and the light emitting element layer 130 are separately described, but the present disclosure is not limited thereto. For example, the circuit layer 120 and the light emitting element layer 130 may also be integrated.

In one or more embodiments, the display panel 100 may further include a sensor layer 150 (e.g., a touch sensor layer) including sensor electrodes of a touch sensor. For example, the display panel 100 may further include a sensor layer 150 arranged on the encapsulation layer 140. The type (kind), structure, and/or position of the sensor layer 150 may be variously changed depending on the embodiment.

The substrate 110 is a base member for forming the display panel 100 and may include a display area DA and a non-display area NA. The non-display area NA of the substrate 110 may further include a pad area. For example, the substrate 110 may include a first pad area PP1 and a second pad area PP2 positioned in different portions of the non-display area NA.

In one or more embodiments, the substrate 110 may be a flexible substrate capable of being deformed such as by bending, folding, or rolling. The substrate 110 may include an insulating material such as polymer resin. For example, the substrate 110 may be made of polyimide or another insulating material. In other embodiments, the substrate 110 may be a substrate that includes an insulating material such as glass and that has rigid characteristics and may not be bent.

The circuit layer 120 may include pixel circuits provided in the pixels PX and lines connected to the pixels PX. For example, the circuit layer 120 includes circuit elements constituting a pixel circuit for each of the pixels PX and lines (e.g., scan lines, data lines, power lines, and/or the like) connected to the pixels PX.

FIG. 3 illustrates a first transistor TFT1 (also referred to as a “first thin film transistor”), a second transistor TFT2 (also referred to as a “second thin film transistor”), and a capacitor Cst included in the pixel circuit of each pixel PX among the elements that may be provided to the circuit layer 120 in the display area DA. In one or more embodiments, FIG. 3 illustrates the display panel 100 having a structure in which the first transistor TFT1 and the second transistor TFT2 include a first active layer ACT1 and a second active layer ACT2, respectively, arranged on different layers within the circuit layer 120. However, the present disclosure is not limited thereto. For example, the active layers of the transistors included in the pixel circuit may be arranged on the same layer.

In one or more embodiments, the first transistor TFT1 may represent a first type (kind) transistor (e.g., a P-type (kind) transistor) including a first semiconductor material (e.g., polysilicon) among the transistors constituting each pixel circuit. FIG. 3 illustrates, as the first transistor TFT1, a transistor connected to the light emitting element EL of the corresponding pixel PX through a connection electrode CNE. The second transistor TFT2 may represent a second type (kind) transistor (e.g., an N-type (kind) transistor) including a second semiconductor material (e.g., an oxide semiconductor) among the transistors constituting each pixel circuit.

The cross-section of the pixels PX may be variously changed depending on the type (kind) and/or structure of each pixel PX and the display panel 100 including the same. For example, the positions and formation order of the first transistor TFT1, the second transistor TFT2, and the capacitor Cst may vary depending on the embodiment.

The circuit layer 120 may include semiconductor layers for forming the circuit elements and the lines, conductive layers, and insulating layers arranged between and/or around the semiconductor layers and conductive layers. For example, the circuit layer 120 may include a first semiconductor layer SCL1 (e.g., a polysilicon semiconductor layer), a first gate insulating layer 123 (also referred to as a “first insulating layer INS” or a “first inorganic insulating layer”), a first gate conductive layer GCDL1, a second gate insulating layer 124 (also referred to as a “second inorganic insulating layer”), a second gate conductive layer GCDL2, a first interlayer insulating layer 125 (also referred to as a “third inorganic insulating layer”), a second semiconductor layer SCL2 (e.g., an oxide semiconductor layer), a third gate insulating layer 126 (also referred to as a “fourth inorganic insulating layer”), a third gate conductive layer GCDL3, a second interlayer insulating layer 127 (also referred to as a “fifth inorganic insulating layer”), a first source-drain conductive layer SCDL1 (also referred to as a “first data conductive layer”), and a first planarization layer 128 (also referred to as a “first organic insulating layer”) that are sequentially arranged on the substrate 110 based on (e.g., along) the third direction DR3.

In one or more embodiments, the circuit layer 120 may not include (e.g., may exclude) the second semiconductor layer SCL2 and/or the like. For example, in the display panel 100 in which the pixels PX include transistors of the same type (kind) and the active layers of the transistors are all formed on the same layer, the circuit layer 120 may not include (e.g., may exclude) the second semiconductor layer SCL2, the third gate insulating layer 126, and/or the third gate conductive layer GCDL3. In one or more embodiments, the circuit layer 120 may further include at

least one conductive layer and at least one insulating layer arranged on the first planarization layer 128. For example, the circuit layer 120 may include a second source-drain conductive layer SCDL2 (also referred to as a “second data conductive layer”) and a second planarization layer 129 (also referred to as a “second organic insulating layer”) that are sequentially arranged on the first planarization layer 128.

In one or more embodiments, the circuit layer 120 may further include at least one insulating layer and/or at least one conductive layer arranged between the substrate 110 and the first semiconductor layer SCL1. For example, the circuit layer 120 may include a buffer layer 121 (or a barrier layer) and a barrier layer 122 (or a buffer layer) arranged between the substrate 110 and the first semiconductor layer SCL1. In one or more embodiments, the circuit layer 120 may further include a lower conductive layer arranged between the buffer layer 121 and the barrier layer 122 and including at least one line and/or a conductive light blocking layer.

At least some of the insulating layers provided in the circuit layer 120 in the display area DA may also be arranged in the non-display area NA. For example, all of the inorganic insulating layers (e.g., the buffer layer 121, the barrier layer 122, the first gate insulating layer 123, the second gate insulating layer 124, the first interlayer insulating layer 125, the third gate insulating layer 126, and the second interlayer insulating layer 127) provided in the circuit layer 120, or at least two inorganic insulating layers selected from among the inorganic insulating layers, may also be arranged around the pads arranged in the non-display area NA.

The buffer layer 121 and the barrier layer 122 may include at least one inorganic insulating layer including an inorganic insulating material (e.g., silicon nitride, silicon oxide, silicon oxynitride, titanium oxide, aluminum oxide, and/or other inorganic insulating materials). The buffer layer 121 and the barrier layer 122 may protect the pixels PX from moisture permeating through the substrate 110, which may be vulnerable to moisture permeation. The material of the buffer layer 121 and the barrier layer 122 may be variously changed depending on the embodiment.

A first transistor TFT1, a second transistor TFT2, and a capacitor Cst may be arranged on one surface of the substrate 110 including the buffer layer 121 and the barrier layer 122.

The first transistor TFT1 may include a first active layer ACT1 and a first gate electrode G1. In one or more embodiments, the first transistor TFT1 may further include a first source electrode S1 and a first drain electrode D1 connected to the first active layer ACT1. In other embodiments, the first transistor TFT1 does not include a separate first source electrode S1 and/or first drain electrode D1, but may include a source electrode and/or a drain electrode formed integrally with a source region and/or a drain region of the first active layer ACT1.

The second transistor TFT2 may include a second active layer ACT2 and a second gate electrode G2. In one or more embodiments, the second transistor TFT2 may further include a back-gate electrode BG. In one or more embodiments, the second transistor TFT2 may further include a second source electrode S2 and a second drain electrode D2 connected to the second active layer ACT2. In other embodiments, the second thin film transistor TFT2 does not include a separate second source electrode S2 and/or second drain electrode D2, but may include a source electrode and/or a drain electrode formed integrally with a source region and/or a drain region of the second active layer ACT2.

The capacitor Cst may include a first capacitor electrode CAE1 and a second capacitor electrode CAE2. The first capacitor electrode CAE1 and the second capacitor electrode CAE2 may overlap each other with at least one insulating film interposed therebetween.

For example, the first semiconductor layer SCL1 may be arranged on the buffer layer 121 and the barrier layer 122. The first semiconductor layer SCL1 may include the first active layer ACT1 of the first transistor TFT1. For example, the first semiconductor layer SCL1 may include active layers of first type (kind) transistors among the transistors constituting the pixel circuits of the pixels PX.

The first active layer ACT1 may be provided in the first semiconductor layer SCL1 and may include a first semiconductor material (e.g., polysilicon). The first active layer ACT1 may include a channel region overlapping the first gate electrode G1, and a source region and a drain region positioned on both sides (e.g., opposite sides) of the channel region. In one or more embodiments, the source and drain regions of the first active layer ACT1 may be connected to the first source electrode S1 and the first drain electrode D1, respectively. In other embodiments, the source region and/or the drain region of the first active layer ACT1 may be the source electrode and/or the drain electrode of the first transistor TFT1.

A first gate insulating layer 123 may be arranged on the first semiconductor layer SCL1. The first gate insulating layer 123 may cover the first semiconductor layer SCL1.

A first gate conductive layer GCDL1 may be arranged on the first gate insulating layer 123. The first gate conductive layer GCDL1 may include the first gate electrode G1 of the first transistor TFT1. The first gate electrode G1 may be provided in the first gate conductive layer GCDL1 to overlap a portion (e.g., a channel region) of the first active layer ACT1.

In one or more embodiments, the first gate conductive layer GCDL1 may further include at least one line (or a portion of the at least one line), conductive pattern (e.g., a bridge pattern), and/or capacitor electrode. As an example, the first gate conductive layer GCDL1 may further include a first capacitor electrode CAE1 of the capacitor Cst.

A second gate insulating layer 124 may be arranged on the first gate conductive layer GCDL1. The second gate insulating layer 124 may cover the first gate conductive layer GCDL1.

A second gate conductive layer GCDL2 may be arranged on the second gate insulating layer 124. The second gate conductive layer GCDL2 may include one electrode of the capacitor Cst, for example, the second capacitor electrode CAE2. In one or more embodiments, the second gate conductive layer GCDL2 may further include at least one electrode, line (or a portion of the at least one line), and/or conductive pattern (e.g., a bridge pattern). For example, the second gate conductive layer GCDL2 may further include a back-gate electrode BG connected to the second gate electrode G2 of the second transistor TFT2.

A first interlayer insulating layer 125 may be arranged on the second gate conductive layer GCDL2. The first interlayer insulating layer 125 may cover the second gate conductive layer GCDL2.

A second semiconductor layer SCL2 may be arranged on the first interlayer insulating layer 125. The second semiconductor layer SCL2 may include the second active layer ACT2 of the second transistor TFT2. For example, the second semiconductor layer SCL2 may include active layers of second type (kind) transistors among the transistors constituting the pixel circuits of the pixels PX.

The second active layer ACT2 may be provided in the second semiconductor layer SCL2 and may include a second semiconductor material (e.g., an oxide semiconductor) different from the first semiconductor material. For example, the second active layer ACT2 may include IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The second active layer ACT2 may include a channel region overlapping the second gate electrode G2, and a source region and a drain region positioned on both sides (e.g., opposite sides) of the channel region. In one or more embodiments, the source and drain regions of the second active layer ACT2 may be connected to the second source electrode S2 and the second drain electrode D2, respectively. In other embodiments, the source region and/or the drain region of the second active layer ACT2 may be the source electrode and/or the drain electrode of the second transistor TFT2.

A third gate insulating layer 126 may be arranged on the second semiconductor layer SCL2. The third gate insulating layer 126 may cover the second gate conductive layer GCDL2 and the second semiconductor layer SCL2.

A third gate conductive layer GCDL3 may be arranged on the third gate insulating layer 126. The third gate conductive layer GCDL3 may include the second gate electrode G2 of the second transistor TFT2. The second gate electrode G2 may be provided in the third gate conductive layer GCDL3 to overlap a portion (e.g., a channel region) of the second active layer ACT2. In one or more embodiments, the third gate conductive layer GCDL3 may further include at least one line (or a portion of the at least one line), conductive pattern (e.g., a bridge pattern), and/or capacitor electrode.

In one or more embodiments, each of the electrodes, the conductive patterns and/or the lines provided in the first gate conductive layer GCDL1, the second gate conductive layer GCDL2, and the third gate conductive layer GCDL3 may include a conductive material (e.g., at least one of molybdenum (Mo), aluminum (AI), chromium (Cr), gold (Au), silver (Ag), titanium (Ti), nickel (Ni), neodymium (Nd), copper (Cu), and/or other metals, an alloy thereof, and/or other conductive materials), and may have a single-layer or multi-layer structure. For example, each of the electrodes, the conductive patterns, and/or the lines provided in the first gate conductive layer GCDL1, the second gate conductive layer GCDL2, and the third gate conductive layer GCDL3 may include molybdenum (Mo) or other metal materials. At least two conductive layers of the first gate conductive layer GCDL1, the second gate conductive layer GCDL2, and/or the third gate conductive layer GCDL3 may include the same material or different materials. The materials of each of the first gate conductive layer GCDL1, the second gate conductive layer GCDL2, and the third gate conductive layer GCDL3 are not limited and may be variously changed depending on the embodiment.

A second interlayer insulating layer 127 may be arranged on the third gate conductive layer GCDL3. The second interlayer insulating layer 127 may cover the third gate conductive layer GCDL3.

In one or more embodiments, the first gate insulating layer 123, the second gate insulating layer 124, the first interlayer insulating layer 125, the third gate insulating layer 126, and the second interlayer insulating layer 127 may be inorganic insulating layers including an inorganic insulating material (e.g., silicon nitride, silicon oxide, silicon oxynitride, titanium oxide, aluminum oxide, and/or other inorganic insulating materials), and may each have a single-layer or multi-layer structure. At least two insulating layers of the first gate insulating layer 123, the second gate insulating layer 124, the first interlayer insulating layer 125, the third gate insulating layer 126, and/or the second interlayer insulating layer 127 may include the same material or different materials. The materials of each of the first gate insulating layer 123, the second gate insulating layer 124, the first interlayer insulating layer 125, the third gate insulating layer 126, and the second interlayer insulating layer 127 are not limited, and may be variously changed depending on the embodiment.

A first source-drain conductive layer SCDL1 may be arranged on the second interlayer insulating layer 127. The first source-drain conductive layer SCDL1 may include the first source electrode S1 and the first drain electrode D1 of the first transistor TFT1 (or at least one bridge pattern connected to the first source electrode S1 and/or the first drain electrode D1 of the first transistor TFT1), and the second source electrode S2 and the second drain electrode D2 of the second transistor TFT2 (or at least one bridge pattern connected to the second source electrode S2 and/or the second drain electrode D2 of the second transistor TFT2).

The first source electrode S1 may be connected to the source region of the first active layer ACT1. For example, the first source electrode S1 may be provided in the first source-drain conductive layer SCDL1, and may be connected to the source region of the first active layer ACT1 through a contact hole penetrating through the first gate insulating layer 123, the second gate insulating layer 124, the first interlayer insulating layer 125, the third gate insulating layer 126, and the second interlayer insulating layer 127.

The first drain electrode D1 may be connected to the drain region of the first active layer ACT1. For example, the first drain electrode D1 may be provided in the first source-drain conductive layer SCDL1, and may be connected to the drain region of the first active layer ACT1 through a contact hole penetrating through the first gate insulating layer 123, the second gate insulating layer 124, the first interlayer insulating layer 125, the third gate insulating layer 126, and the second interlayer insulating layer 127.

The second source electrode S2 may be connected to the source region of the second active layer ACT2. For example, the second source electrode S2 may be provided in the first source-drain conductive layer SCDL1 and may be connected to the source region of the second active layer ACT2 through a contact hole penetrating through the third gate insulating layer 126 and the second interlayer insulating layer 127.

The second drain electrode D2 may be connected to the drain region of the second active layer ACT2. For example, the second drain electrode D2 may be provided in the first source-drain conductive layer SCDL1 and may be connected to the drain region of the second active layer ACT2 through a contact hole penetrating through the third gate insulating layer 126 and the second interlayer insulating layer 127.

In one or more embodiments, the first source-drain conductive layer SCDL1 may further include at least one line (or a portion of the at least one line) and/or conductive pattern (e.g., a bridge pattern). As an example, the first source-drain conductive layer SCDL1 may further include data lines and/or at least one power line.

A first planarization layer 128 may be arranged on the first source-drain conductive layer SCDL1. The first planarization layer 128 may cover the first source-drain conductive layer SCDL1.

A second source-drain conductive layer SCDL2 may be arranged on the first planarization layer 128. The second source-drain conductive layer SCDL2 may include a connection electrode CNE. The connection electrode CNE may be provided in the second source-drain conductive layer SCDL2 and may be connected to the first drain electrode D1 of the first transistor TFT1 through a contact hole or a via hole penetrating through the first planarization layer 128. In one or more embodiments, the second source-drain conductive layer SCDL2 may further include at least one line (or a portion of the at least one line) and/or conductive pattern (e.g., a bridge pattern). As an example, the second source-drain conductive layer SCDL2 may further include at least one power line.

In one or more embodiments, each of the electrodes, the conductive patterns, and/or the lines provided in the first source-drain conductive layer SCDL1 and the second source-drain conductive layer SCDL2 may include a conductive material (e.g., at least one of molybdenum (Mo), aluminum (Al), chromium (Cr), gold (Au), silver (Ag), titanium (Ti), nickel (Ni), neodymium (Nd), copper (Cu), and/or other metals, an alloy thereof, and/or other conductive materials), and may have a single-layer or multi-layer structure. As an example, each of the electrodes, the conductive patterns, and/or lines provided in the first source-drain conductive layer SCDL1 and the second source-drain conductive layer SCDL2 may be formed in a triple-layer structure of titanium (Ti)/aluminum (Al)/titanium (Ti). The first source-drain conductive layer SCDL1 and the second source-drain conductive layer SCDL2 may include the same material or different materials. The materials and/or structures of each of the first source-drain conductive layer SCDL1 and the second source-drain conductive layer SCDL2 may be variously changed depending on the embodiment.

A second planarization layer 129 may be arranged on the second source-drain conductive layer SCDL2. The second planarization layer 129 may cover the second source-drain conductive layer SCDL2.

In one or more embodiments, the first planarization layer 128 and the second planarization layer 129 may be an organic insulating film including an organic insulating material (e.g., acryl resin, epoxy resin, phenolic resin, polyamide resin, polyimide resin, and/or other organic insulating materials) for planarization of the circuit layer 120, and may each have a single-layer or multi-layer structure. The first planarization layer 128 and the second planarization layer 129 may include the same material or different materials. The materials of each of the first planarization layer 128 and the second planarization layer 129 are not limited, and may be variously changed depending on one or more embodiment.

The light emitting element layer 130 may be arranged on the circuit layer 120 and may be positioned in the display area DA. For example, the light emitting element layer 130 may be arranged on the circuit layer 120 in the display area DA.

The light emitting element layer 130 may include light emitting elements EL of the pixels PX. For example, the light emitting element layer 130 may include a pixel defining film 131 (also referred to as a “bank”) that partitions a light emitting area EA of each of the pixels PX and a light emitting element EL positioned in each light emitting area EA. In one or more embodiments, the light emitting element layer 130 may further include a spacer 132 arranged on a portion of the pixel defining film 131.

Each light emitting element EL may include a first electrode ET1 (e.g., an anode electrode) connected to at least one transistor (e.g., the first transistor TFT1) included in the corresponding pixel PX through at least one connection electrode CNE, and a light emitting layer EML and a second electrode ET2 (e.g., a cathode electrode) that are sequentially arranged on the first electrode ET1. In one or more embodiments, the light emitting element EL may further include a first intermediate layer (e.g., a hole layer including a hole transporting layer) interposed between the first electrode ET1 and the light emitting layer EML, and a second intermediate layer (e.g., an electron layer including an electron transporting layer) interposed between the light emitting layer EML and the second electrode ET2.

The first electrode ET1 of the light emitting element EL may be arranged on the circuit layer 120. For example, the first electrode ET1 may be arranged on the second planarization layer 129 to correspond to each light emitting area EA. The first electrode ET1 may be connected to the connection electrode CNE through a contact hole or a via hole penetrating through the second planarization layer 129.

The first electrode ET1 may include a conductive material. In one or more embodiments, the first electrode ET1 may include a metal material with high reflectivity.

For example, the first electrode ET1 may have a single-layer structure of molybdenum (Mo), titanium (Ti), copper (Cu), and/or aluminum (Al), or may have a multi-layer structure (e.g., ITO/Mg, ITO/MgF, ITO/Ag, ITO/Ag/ITO, and/or the like) including indium-tin-oxide (ITO), indium-zinc-oxide (IZO), zinc oxide (ZnO), indium oxide (In₂O₃), and silver (Ag), magnesium (Mg), aluminum (AI), platinum (Pt), lead (Pb), gold (Au), and/or nickel (Ni).

The light emitting layer EML of the light emitting element EL may include a high molecular material or a low molecular material. The light emitted from the light emitting layer EML may contribute to displaying an image. In one or more embodiments, the light emitting layer EML may be provided for each pixel PX, and the light emitting layer EML of each pixel PX may be to emit visible light of a color corresponding to the corresponding pixel PX. In one or more embodiments, the light emitting layer EML may be a common layer shared by pixels PX of different colors, and wavelength conversion layers and/or color filters corresponding to the color (or wavelength band) of light to be emitted from each pixel PX may be arranged in the light emitting areas EA of at least some of the pixels PX.

The second electrode ET2 of the light emitting element EL may include a conductive material. In one or more embodiments, the second electrode ET2 may be a common film formed over the entire display area DA to cover the light emitting layer EML and the pixel defining film 131. In one or more embodiments, the second electrode ET2 may be formed of a transparent conductive material (TCO) such as ITO or IZO capable of transmitting light, or a semi-transmissive conductive material such as magnesium (Mg), silver (Ag), or an alloy of magnesium (Mg) and silver (Ag).

The pixel defining film 131 may have an opening corresponding to each light emitting area EA and may be around (e.g., surround) the light emitting area EA. For example, the pixel defining film 131 may be formed to cover an edge of the first electrode ET1 of the light emitting element EL and may include an opening that exposes the remaining portion of the first electrode ET1. An area where the exposed first electrode ET1 and the light emitting layer EML overlap (or an area including the same) may be defined as a light emitting area EA of each pixel PX.

In one or more embodiments, the pixel defining film 131 may include at least one organic insulating layer including an organic insulating material. For example, the pixel defining film 131 may include a polyacrylates resin, an epoxy resin, a phenolic resin, a polyamides resin, a polyimides resin, an unsaturated polyesters resin, a poly phenylene ethers resin, a polyphenylene sulfides resin, benzocyclobutene (BCB), or one or more other organic insulating materials.

The spacer 132 may be arranged on a portion of the pixel defining film 131. The spacer 132 may include at least one organic insulating layer including an organic insulating material. The spacer 132 may include the same material as the pixel defining film 131 or may include a different material from the pixel defining film 131. In one or more embodiments, the pixel defining film 131 and the spacer 132 may be sequentially formed through each mask process (e.g., separate mask processes). In one or more embodiments, the pixel defining film 131 and the spacer 132 may be concurrently (e.g., simultaneously) formed using a halftone mask. In this case, the pixel defining film 131 and the spacer 132 may be viewed as one insulating film that is integrated with each other.

An encapsulation layer 140 may be arranged on the light emitting element layer 130. The encapsulation layer 140 may cover the light emitting element layer 130 in the display area DA and extend to the non-display area NA to be in contact with the circuit layer 120. For example, the encapsulation layer 140 may be arranged in the display area DA to cover the light emitting element layer 130, and an end portion of the encapsulation layer 140 may be positioned in a portion of the non-display area NA adjacent to the display area DA. The encapsulation layer 140 may block or reduce the permeation of oxygen or moisture into the light emitting element layer 130, and may alleviate or reduce electrical and/or physical shock to the circuit layer 120 and the light emitting element layer 130.

In one or more embodiments, the encapsulation layer 140 may have a multi-layer structure including a first encapsulation layer 141, a second encapsulation layer 142, and a third encapsulation layer 143 that are sequentially arranged on the light emitting element layer 130. The first encapsulation layer 141 and the third encapsulation layer 143 may be inorganic encapsulation layers including an inorganic material, and the second encapsulation layer 142 may be an organic encapsulation layer including an organic material.

In one or more embodiments, the display panel 100 may further include at least one dam to limit the extent to which the organic material of the second encapsulation layer 142 diffuses. For example, the display panel 100 may include a dam around (e.g., surrounding) the display area DA.

A sensor layer 150 may be arranged on the encapsulation layer 140 in the display area DA. In one or more embodiments, the sensor layer 150 may include a first sensor conductive layer TCDL1 and a second sensor conductive layer TCDL2. In one or more embodiments, the sensor layer 150 may also include a first sensor insulating layer 151, a second sensor insulating layer 152, and a passivation layer 153 sequentially arranged on the encapsulation layer 140.

The first sensor insulating layer 151 may be arranged on the encapsulation layer 140. The first sensor insulating layer 151 may include at least one inorganic insulating layer including an inorganic insulating material. The first sensor insulating layer 151 may cover the encapsulation layer 140 to protect the encapsulation layer 140 and prevent or reduce moisture permeation.

The first sensor conductive layer TCDL1 may be arranged on the first sensor insulating layer 151. In one or more embodiments, the first sensor conductive layer TCDL1 may include bridge patterns BRP of the first sensor electrodes TS1 and/or the second sensor electrodes TS2. In other embodiments, the first sensor conductive layer TCDL1 may include the first sensor electrodes TS1 and/or the second sensor electrodes TS2.

The second sensor insulating layer 152 may be arranged on the first sensor conductive layer TCDL1. The second sensor insulating layer 152 may cover the first sensor conductive layer TCDL1. The second sensor insulating layer 152 may include at least one inorganic insulating layer including an inorganic insulating material.

The second sensor conductive layer TCDL2 may be arranged on the second sensor insulating layer 152. In one or more embodiments, the second sensor conductive layer TCDL2 may include the first sensor electrodes TS1 and/or the second sensor electrodes TS2. In other embodiments, the second sensor conductive layer TCDL2 may include bridge patterns BRP of the first sensor electrodes TS1 and/or the second sensor electrodes TS2.

Each of the electrodes, the conductive patterns, and/or the lines provided in the first sensor conductive layer TCDL1 and the second sensor conductive layer TCDL2 may include a conductive material (e.g., at least one of molybdenum (Mo), aluminum (Al), chromium (Cr), gold (Au), silver (Ag), titanium (Ti), nickel (Ni), neodymium (Nd), copper (Cu), and/or other metals, an alloy thereof, a transparent conductive material such as ITO or IZO, and/or other conductive materials). Each of the electrodes, the conductive patterns, and/or the lines provided in the first sensor conductive layer TCDL1 and the second sensor conductive layer TCDL2 may have a single-layer or multi-layer structure.

In one or more embodiments, the first sensor conductive layer TCDL1 and/or the second sensor conductive layer TCDL2 may include mesh-shaped conductive patterns. For example, the first sensor electrodes TS1, the second sensor electrodes TS2, and the bridge patterns BRP may be formed as mesh-shaped patterns including openings corresponding to the light emitting areas EA of the pixels PX. Accordingly, light loss of the display panel 100 may be prevented or reduced, and light efficiency thereof may be increased.

The passivation layer 153 may be arranged on the second sensor conductive layer TCDL2. The passivation layer 153 may include at least one insulating layer including an inorganic insulating material and/or an organic insulating material. In one or more embodiments, the passivation layer 153 may be made of an organic insulating material (e.g., a negative photoresist material) that may be formed through a low-temperature process, but the material of the passivation layer 153 is not limited thereto.

In one or more embodiments, the sensor layer 150 may further include lines connected to the first sensor electrodes TS1 and the second sensor electrodes TS2. For example, the sensor layer 150 may further include sensor lines connected to the first sensor electrodes TS1 and the second sensor electrodes TS2 inside and/or around the display area DA and passing through the non-display area NA.

In one or more embodiments, the sensor layer 150 may be formed integrally with the display panel 100. For example, portions of the first sensor electrodes TS1, the second sensor electrodes TS2, and the sensor lines inside and/or around the display area DA and passing through the non-display area NA may be formed on the encapsulation layer 140 to be arranged on top of the pixels PX formed in the circuit layer 120 and the light emitting element layer 130, and other portions of the sensor lines may be formed on the substrate 110 and/or the circuit layer 120.

A touch input occurring in the display area DA may be sensed by the touch sensor including the first sensor electrodes TS1 and the second sensor electrodes TS2. For example, the first sensor electrodes TS1 and the second sensor electrodes TS2 may be touch electrodes for detecting a user's touch or for detecting whether the user approaches.

In one or more embodiments, the display device 10 may further include additional elements arranged on the sensor layer 150. For example, the display device 10 may further include at least one of an optical layer (e.g., an anti-reflection layer including a polarizing layer and/or a color filter layer) and/or a protective layer (e.g., a window or a protective film) arranged on the sensor layer 150. In one or more embodiments, the optical layer and/or the protective layer may be provided on the display panel 100. For example, the optical layer and/or the protective layer may be formed on the sensor layer 150 and may be manufactured integrally with the display panel 100. In one or more embodiments, the optical layer and/or the protective layer may be manufactured separately from the display panel 100 and attached to the display panel 100 through an adhesive layer and/or the like.

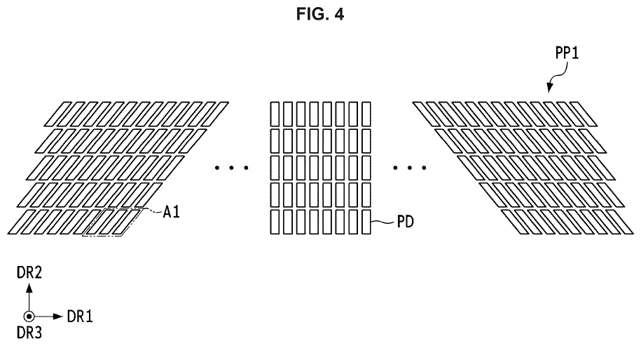

FIG. 4 is a plan view illustrating pads in a first pad area according to one or more embodiments of the present disclosure. For example, FIG. 4 illustrates an example of pads PD positioned in the first pad area PP1 and connected to output terminals of the driving circuit 200.

Referring to FIG. 4 in addition to FIGS. 1 and 2, a plurality of pads PD may be arranged in the first pad area PP1 to which the driving circuit 200 is connected. The pads PD may include pads for transmitting signals (e.g., image data and related signals, power, and/or the like) to the driving circuit 200, and pads for receiving signals (e.g., data signals, gate driver control signals, and/or the like) output from the driving circuit 200. The illustrated pads PD may be pads connected to the output terminals of the driving circuit 200 to receive the signals output from the driving circuit 200. Most of the pads PD may be electrically connected to data lines positioned in the display area

DA, and may receive data signals (e.g., respective data voltages) applied to the pixels PX through the data lines from the driving circuit 200. For electrical connection of signal lines such as the data lines and the pads PD, lines connected to the pads PD may be positioned between the first pad area PP1 and the display area DA.

As the resolution of the display device increases, the plurality of pads PD arranged in the first pad area PP1 may increase, and as a result, the pads PD may be arranged in a plurality of rows and columns. In each column, the pads PD may be arranged at set or predetermined intervals along the first direction DR1 and the second direction DR2.

In one or more embodiments, each pad PD may have an overall quadrangular planar shape. The pad PD may have a long side (length) and a short side (width). The short side of the pad PD may be parallel to the first direction DR1. The long sides of the pads PD positioned in the left and right areas of the first pad area PP1 may be inclined with respect to the first direction DR1 and the second direction DR2. For example, the pads PD positioned in the central area in the first pad area PP1 may have a rectangular planar shape, and the pads PD positioned in the left and right areas may have a parallelogram planar shape. The pad PD may have a long side and a short side of approximately the same length, or may have one or more suitable planar shapes.

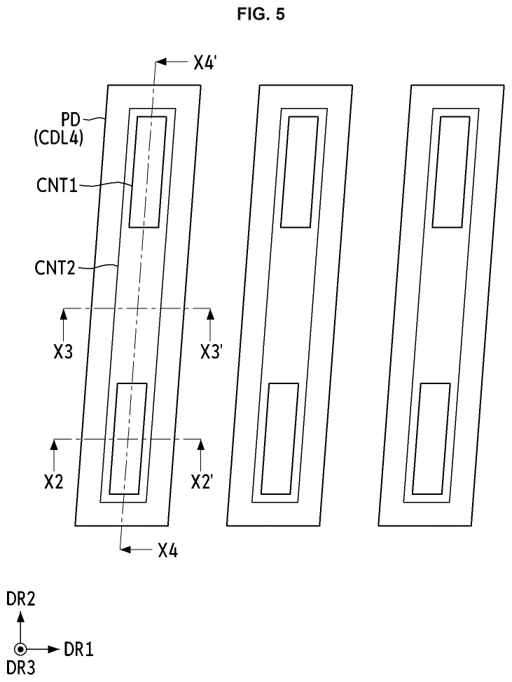

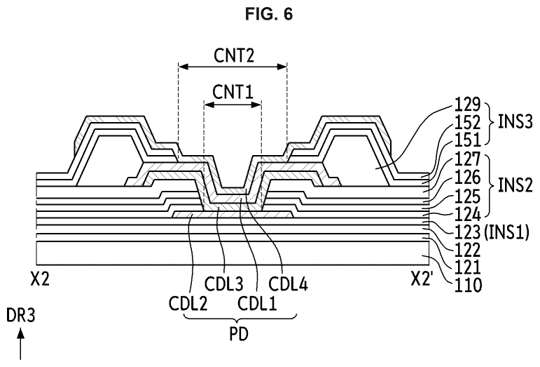

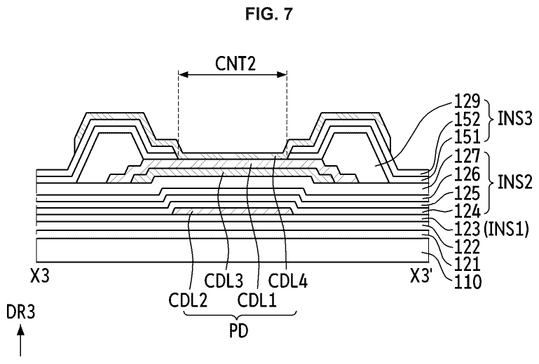

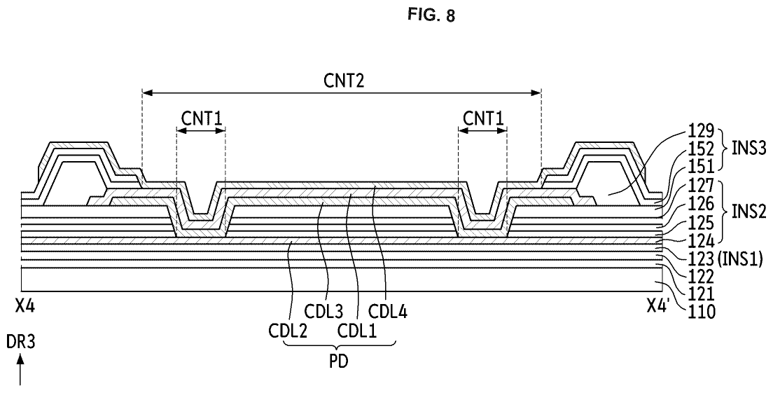

FIG. 5 is a plan view illustrating a pad area of the display panel according to one or more embodiments of the present disclosure. FIGS. 6 to 8 are cross-sectional views illustrating pad areas of the display panel according to one or more embodiments of the present disclosure. For example, FIG. 5 schematically illustrates a portion of the first pad area PP1 corresponding to the area A1 in FIG. 4, according to one or more embodiments of the present disclosure. FIG. 6 illustrates an example of a cross-section of a portion of the first pad area PP1 corresponding to line X2-X2′ in FIG. 5, according to one or more embodiments of the present disclosure. FIG. 7 illustrates an example of a cross-section of a portion of the first pad area PP1 corresponding to line X3-X3′ in FIG. 5, according to one or more embodiments of the present disclosure. FIG. 8 illustrates an example of a cross-section of a portion of the first pad area PP1 corresponding to line X4-X4′ in FIG. 5, according to one or more embodiments of the present disclosure.

The remaining portion of the first pad area PP1 (e.g., the portion where the pads PD having long sides parallel to the second direction DR2 are positioned) and pads PD on the right side of FIG. 4 slanted in the opposite direction to those in FIG. 5 may have a structure that is substantially the same as or similar to a portion of the first pad area PP1 illustrated in FIGS. 5 to 8.

Referring to FIGS. 5 to 8 in addition to FIGS. 1 to 4, the display panel 100 may include a first contact portion CNT1 through which the respective pads PD positioned in the first pad area PP1 are connected to each other, and a second contact portion CNT2 through which the pads PD are connected to the driving circuit 200. For example, the first pad area PP1 may include contact portions CNT1 and CNT2 at positions corresponding to the pads PD, and the pads PD may be exposed in the second contact portion CNT2 and electrically connected to the driving circuit 200.

The display panel 100 may include at least one conductive layer constituting the pads PD positioned in the first pad area PP1 and at least one insulating layer arranged around the at least one conductive layer. For example, each pad PD may include a first conductive layer CDL1, and a first insulating layer INS1 and a second insulating layer INS2 may be arranged under and/or around the first conductive layer CDL1. A third insulating layer INS3 may be arranged above and/or around the first conductive layer CDL1. The first insulating layer INS1, the second insulating layer INS2, and the third insulating layer INS3 may be sequentially arranged on the substrate 110. Each of the first insulating layer INS1, the second insulating layer INS2, and the third insulating layer INS3 may have a single-layer or multi-layer structure.

Each pad PD may have a single-layer or multi-layer structure including the first conductive layer CDL1. In one or more embodiments, each pad PD may have a four-layer structure including a first conductive layer CDL1, a second conductive layer CDL2 arranged below the first conductive layer CDL1, a third conductive layer CDL3 arranged between the first conductive layer CDL1 and the second conductive layer CDL2, and a fourth conductive layer CDL4 arranged on the first conductive layer CDL1. However, the present disclosure is not limited thereto, and the structure of the pad PD may be variously changed. For example, the pad PD may not include (e.g., may exclude) at least one of the second conductive layer CDL2, the third conductive layer CDL3, and/or the fourth conductive layer CDL4.

In one or more embodiments, the first conductive layer CDL1 may be arranged on the same layer as the second source-drain conductive layer SCDL2 in the display area DA, and may be concurrently (e.g., simultaneously) formed using the same material as the electrodes, the conductive patterns, and/or the lines provided in the second source-drain conductive layer SCDL2. For example, the first conductive layer CDL1 may include the same conductive material as the connection electrode CNE of each pixel PX and may be arranged on the same layer as the connection electrode CNE of each pixel PX. In one or more embodiments, the first conductive layer CDL1 may have a cross-sectional structure that is substantially the same as the connection electrode CNE of each pixel PX.

1 The second conductive layer CDL2 may be arranged on the same layer as the first gate conductive layer GCDL1 in the display area DA, and may be concurrently (e.g., simultaneously) formed using the same material as the electrodes, the conductive patterns, and/or the lines provided in the first gate conductive layer GCDL1. For example, the second conductive layer CDL2 may include the same conductive material as the first gate electrode G1 of the first transistor TFT1 and may be arranged on the same layer as the first gate electrode G1.

The third conductive layer CDL3 may be arranged on the same layer as the first source-drain conductive layer SCDL1 in the display area DA, and may be concurrently (e.g., simultaneously) formed using the same material as the electrodes, the conductive patterns, and/or the lines provided in the first source-drain conductive layer SCDL1. For example, the third conductive layer CDL3 may include the same conductive material as the first source electrode S1 and/or the first drain electrode D1 of the first transistor TFT1, and/or the second source electrode S2 and/or the second drain electrode D2 of the second transistor TFT2, and may be arranged on the same layer. In one or more embodiments, the third conductive layer CDL3 may have a cross-sectional structure that is substantially the same as the first source electrode S1 and/or the first drain electrode D1 of the first transistor TFT1, and/or the second source electrode S2 and/or the second drain electrode D2 of the second transistor TFT2.

The fourth conductive layer CDL4 may be arranged on the same layer as the second sensor conductive layer TCDL2 in the display area DA, and may be concurrently (e.g., simultaneously) formed using the same material as the electrodes, the conductive patterns, and/or the lines provided in the second sensor conductive layer TCDL2. For example, the fourth conductive layer CDL4 may include the same conductive material as the first sensor electrodes TS1 and/or the second sensor electrodes TS2, and may be arranged on the same layer as the first sensor electrodes TS1 and/or the second sensor electrodes TS2.

The conductive layers constituting each pad PD may be electrically connected to each other. For example, the second conductive layer CDL2, the third conductive layer CDL3, the first conductive layer CDL1, and the fourth conductive layer CDL4 constituting each pad PD may be sequentially arranged along the third direction DR3 in the contact portion CNT and may be electrically connected to each other. As an example, the second insulating layer INS2 is partially opened to form a first contact portion CNT1 exposing the second conductive layer CDL2, so that the second conductive layer CDL2 and the third conductive layer CDL3 may be in contact with each other. The third insulating layer INS3 is partially opened to form a second contact portion CNT2 exposing the third conductive layer CDL3, so that the third conductive layer CDL3 and the fourth conductive layer CDL4 may be in contact with each other (via the first conductive layer CDL1).

A buffer layer 121 and/or a barrier layer 122 may be arranged on the substrate 110. The first insulating layer INS1 may be arranged on one surface of the substrate 110 on which the buffer layer 121 and/or the barrier layer 122 are arranged.

The first insulating layer INS1 may mean or refer to one or more insulating layers arranged below the pads PD. For example, the first insulating layer INS1 may be a single-layer or multi-layer insulating layer including the first gate insulating layer 123. In one or more embodiments, the first insulating layer INS1 may be the first gate insulating layer 123. In other embodiments, the first insulating layer INS1 may include the first gate insulating layer 123 and may further include at least one of the buffer layer 121 and the barrier layer 122. When the display panel 100 does not include the first gate insulating layer 123, the first insulating layer INS1 may include at least one of the buffer layer 121 and the barrier layer 122. FIGS. 6 to 8 illustrate one or more embodiments in which the first insulating layer INS1 is the first gate insulating layer 123.

The second insulating layer INS2 may be arranged on the first insulating layer INS1. The second insulating layer INS2 may mean or refer to one or more insulating layers arranged below the first conductive layer CDL1. For example, the second insulating layer INS2 may include one or more inorganic insulating layers arranged between the first gate conductive layer GCDL1 provided with the second conductive layer CDL2 and the second source-drain conductive layer SCDL2 provided with the first conductive layer CDL1. As an example, the second insulating layer INS2 may be a single-layer or multi-layer insulating layer including at least one of the second gate insulating layer 124, the first interlayer insulating layer 125, the third gate insulating layer 126, and the second interlayer insulating layer 127. FIGS. 6 to 8 illustrate one or more embodiments in which the second insulating layer INS2 includes the second gate insulating layer 124, the first interlayer insulating layer 125, the third gate insulating layer 126, and the second interlayer insulating layer 127.

The third insulating layer INS3 may be arranged on the second insulating layer INS2. The third insulating layer INS3 may mean or refer to one or more insulating layers arranged on the first conductive layer CDL1. For example, the third insulating layer INS3 may include one or more organic and/or inorganic insulating layers arranged on the first conductive layer CDL1. In one or more embodiments, the third insulating layer INS3 may include at least one insulating layer arranged between the pixels PX and the sensor electrodes (the first sensor electrodes TS1 and/or the second sensor electrodes TS2). As an example, the third insulating layer INS3 may include a single-layer insulating layer including one of the first planarization layer 128 or the second planarization layer 129, and may include a single-layer or multi-layer insulating layer including at least one of the first sensor insulating layer 151 and/or the second sensor insulating layer 152. FIGS. 6 to 8 illustrate one or more embodiments in which the third insulating layer INS3 includes the second planarization layer 129, the first sensor insulating layer 151, and the second sensor insulating layer 152.

The second insulating layer INS2 and the third insulating layer INS3 may be opened so that the pads PD may be connected to each other. For example, the second insulating layer INS2 may include a first opening and the third insulating layer INS3 may include a second opening.

The second insulating layer INS2 may include the first opening exposing the second conductive layer CDL2 to form a first contact portion CNT1. The second conductive layer CDL2 may be exposed in the first contact portion CNT1 through the first opening. The second conductive layer CDL2 may be covered with the second insulating layer INS2 around the first contact portion CNT1. For example, the second insulating layer INS2 may cover an edge area of the second conductive layer CDL2. The second conductive layer CDL2 may be arranged between the first insulating layer INS1 and the third conductive layer CDL3.

The third conductive layer CDL3 may be arranged on the second conductive layer CDL2 exposed through the first opening in the first contact portion CNT1. For example, the third conductive layer CDL3 may be arranged between the second conductive layer CDL2 and the first conductive layer CDL1, and may be arranged inside the first opening in the first contact portion CNT1. Around the first contact portion CNT1, the third conductive layer CDL3 may be arranged on the second insulating layer INS2 and may be covered with the first conductive layer CDL1. For example, the first conductive layer CDL1 may completely cover the edge area of the third conductive layer CDL3.

The third insulating layer INS3 may cover the first conductive layer CDL1 around the second contact portion CNT2. For example, the third insulating layer INS3 may expose the first conductive layer CDL1 through the second opening and cover the first conductive layer CDL1 around the second contact portion CNT2.

The fourth conductive layer CDL4 may be arranged on the first conductive layer CDL1 in the second contact portion CNT2. For example, the fourth conductive layer CDL4 may be positioned inside the second opening in the second contact portion CNT2 and in contact with the first conductive layer CDL1. The fourth conductive layer CDL4 may be arranged on the third insulating layer INS3 around the second contact portion CNT2.

In one or more embodiments, the fourth conductive layer CDL4 may be formed concurrently (e.g., simultaneously) using the same material as the electrodes, the conductive patterns, and/or the lines that may be formed in the display area DA after the formation of the first conductive layer CDL1. As an example, the fourth conductive layer CDL4 may be concurrently (e.g., simultaneously) formed using same material as the electrodes, the conductive patterns, and/or the lines that may be provided in the first sensor conductive layer TCDL1 and/or the second sensor conductive layer TCDL2. In one or more embodiments, the third insulating layer INS3 may include the second planarization layer 129, the first sensor insulating layer 151, and the second sensor insulating layer 152, and the fourth conductive layer CDL4 may be concurrently (e.g., simultaneously) formed using the same material as the first sensor electrodes TS1 and/or the second sensor electrodes TS2.

In each pad PD, the conductive layers CDL1, CDL2, CDL3, and CDL4 of the pad PD may be connected to and/or in contact with each other through the contact portions CNT1 and CNT2. The first contact portion CNT1 may be a portion where the second conductive layer CDL2 and the third conductive layer CDL3 of the pad PD are in contact with each other, and the second contact portion CNT2 may be a portion where the first conductive layer CDL1 and the fourth conductive layer CDL4 of the pad PD are in contact with each other.

According to one or more embodiments, each pad PD may include at least two first contact portions CNT1. Here, the two or more first contact portions CNT1 may be arranged in an area that overlaps one fourth conductive layer CDL4. The first contact portions CNT1 may be arranged to be spaced and/or apart (e.g., spaced apart or separated) from each other along a length direction of the pad PD. For example, one first contact portion CNT1 may be arranged on one side of the fourth conductive layer CDL4, and the other first contact portion CNT1 may be arranged on the other side of the fourth conductive layer CDL4.

The first contact portion CNT1 may have a step formed by the first opening of the second insulating layer INS2. For example, the third conductive layer CDL3 of the pad PD is formed along the step of the first opening of the second insulating layer INS2, such that steps may also be formed in the first conductive layer CDL1 and the fourth conductive layer CDL4 sequentially arranged on the third conductive layer CDL3.

Conductive balls of an anisotropic conductive film (ACF) may be arranged on each pad PD and may be connected to bumps of the driving circuit 200. The step formed by the first contact portion CNT1 increases a gap between the bump of the driving circuit 200 and the pad PD, and accordingly, the gap between the pad PD and the bump of the driving circuit 200 may become larger than a size of the conductive ball, resulting in contact defects. For example, the step formed by the first contact portion CNT1 increases the gap between the bump of the driving circuit 200 and the pad PD. Consequently, the gap between the pad PD and the bump of the driving circuit 200 may become larger than the size of the conductive ball, leading to contact defects.

According to one or more embodiments, by providing and arranging two or more first contact portions CNT1, an area of the second contact portion CNT2 that does not overlap the first contact portion CNT1 may be increased.

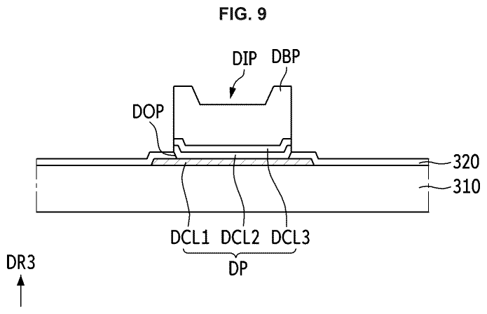

As illustrated in FIGS. 7 and 8, an area of the pad PD that does not overlap the first contact portion CNT1 (e.g., an area where the first contact portions CNT1 are not arranged) may be flat without any steps. For example, a minimum thickness of the area of the pad PD that does not overlap the first contact portion CNT1 may be greater than a minimum thickness of the first contact portion CNT1. Here, the minimum thickness refers to the smallest distance among the distances from the upper surface of the substrate 110 to the upper surface of the fourth conductive layer CDL4 of the pad PD. In one or more embodiments, a maximum distance between the pad PD and a bump DBP in an area where the first contact portion CNT1 and the second contact portion CNT2 overlap may be greater than a maximum distance between the pad PD and the bump DBP (see, e.g., FIG. 9) in an area where the first contact portion CNT1 and the second contact portion CNT2 do not overlap. Here, the distance may be measured in the third direction DR3. As the area of the pad PD that does not overlap the first contact portion CNT1 is formed as thick as the step of the first contact portion CNT1, the gap between the fourth conductive layer CDL4 of the pad PD and the bump of the driving circuit 200 may be reduced. Accordingly, by increasing an effective contact area where the conductive ball may contact between the fourth conductive layer CDL4 of the pad PD and the bump of the driving circuit 200, contact defects in the pad area may be improved (e.g., reduced).

The pad PD according to the above-described embodiments may be more effective in relation to the structure of the bump of the driving circuit 200. Hereinafter, the bump of the driving circuit 200 will be described.

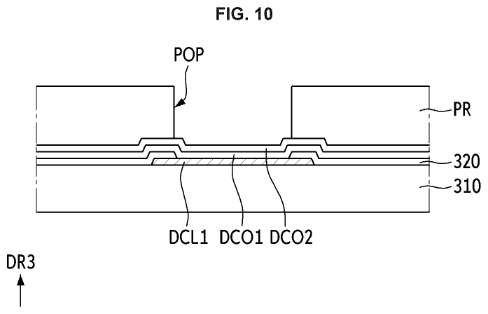

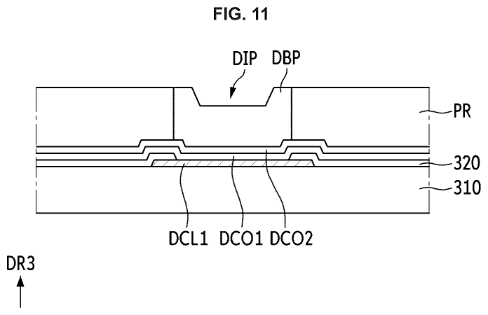

FIG. 9 is a cross-sectional view schematically illustrating a bump of a driving circuit, according to one or more embodiments of the present disclosure. FIGS. 10 and 11 are cross-sectional views illustrating a method of manufacturing the bump of the driving circuit for each step (e.g., act or task) of the process, according to one or more embodiments of the present disclosure.

Referring to FIGS. 9 and 11, the driving circuit 200 according to one or more embodiments may include a driving substrate 310, a driving pad DP arranged on the driving substrate 310, and a bump DBP arranged on the driving pad DP.

The driving substrate 310 may be a semiconductor wafer substrate. For example, the driving substrate may be a silicon (Si)-based substrate.

The driving pad DP may be arranged on the driving substrate 310. The driving pad DP may include a first driving electrode DCL1, a second driving electrode DCL2, and a third driving electrode DCL3. The first driving electrode DCL1 may be arranged on the driving substrate 310. The first driving electrode DCL1 may form a circuit line of the driving substrate 310. The second driving electrode DCL2 may be arranged on the first driving electrode DCL1. The second driving electrode DCL2 may be formed by a deposition method such as sputtering, and may function to increase conductivity and adhesion of the first driving electrode DCL1 and the third driving electrode DCL3. The third driving electrode DCL3 may be arranged on the second driving electrode DCL2. The third driving electrode DCL3 may be formed by a deposition method such as sputtering, and may function to increase conductivity and adhesion with the bump DBP.

A driving insulating layer 320 may be arranged around the driving pad DP. The driving insulating layer 320 may protect the first driving electrode DCL1 of the driving pad DP and insulate the first driving electrodes DCL1 adjacent to each other. The driving insulating layer 320 includes a driving opening DOP so that the first driving electrode DCL1 and the second driving electrode DCL2 may be in contact with each other.

The bump DBP may be arranged on the driving pad DP. The bump DBP is directly connected to the pad PD of the display panel 100 and may include a low-resistance material, for example, a low-resistance metal such as gold. The bump DBP may be aligned with side surfaces of the second driving electrode DCL2 and the third driving electrode DCL3 of the driving pad DP. The bump DBP may have a dimple DIP formed on an upper surface thereof. The dimple DIP may have a groove shape in which the upper surface of the bump DBP is concave. For example, the dimple DIP may have a shape in which the center of bump DBP is concavely recessed in a plan view.

The bump DBP having the dimple DIP may be formed as follows.

As illustrated in FIGS. 10 and 11, a first driving electrode DCL1 is formed on the driving substrate 310, and a driving insulating layer 320 having a driving opening DOP exposing the first driving electrode DCL1 is formed. Thereafter, a second driving electrode material layer DCO1 and a third driving electrode material layer DCO2 may be sequentially stacked.

Next, a mask pattern PR is formed on the third driving electrode material layer DCO2. The mask pattern PR may be formed to include a pattern opening POP exposing an upper surface of the third driving electrode material layer DCO2. The pattern opening POP may partition a position where a bump DBP, which will be described in more detail later, will be formed.

Next, a bump DBP is formed within the pattern opening POP. The bump DBP may be formed by electroplating. For example, the bump DBP can be formed by electroplating using a metal such as gold on the third driving electrode material layer DCO2. Due to the characteristics of the electroplating, the bump DBP may be formed along a lower step. Accordingly, the bump DBP may be formed to have the dimple DIP on the upper surface thereof due to the lower step. In one or more embodiments, the driving circuit 200 as illustrated in FIG. 9 may be manufactured by removing the mask pattern PR, and then etching the second and third driving electrode material layers DCO1 and DCO2 using the bump DBP as a mask.

As described above, the bump DBP of the driving circuit 200 may have a structure in which the dimple DIP is formed on the upper surface. Hereinafter, a structure in which the bump DBP of the driving circuit 200 having the dimple DIP and the pad PD of the display panel 100 are coupled will be described with reference to other drawings.

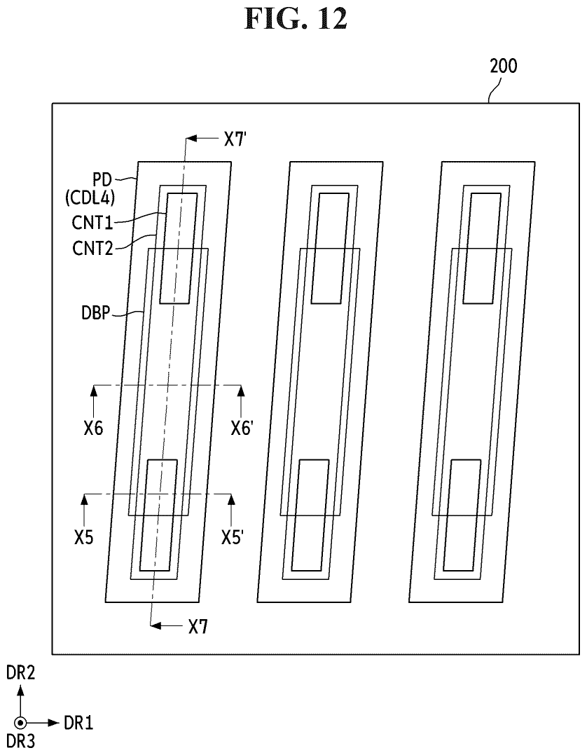

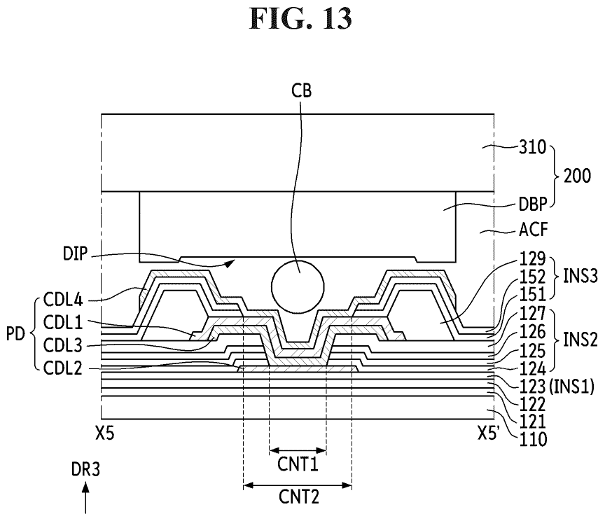

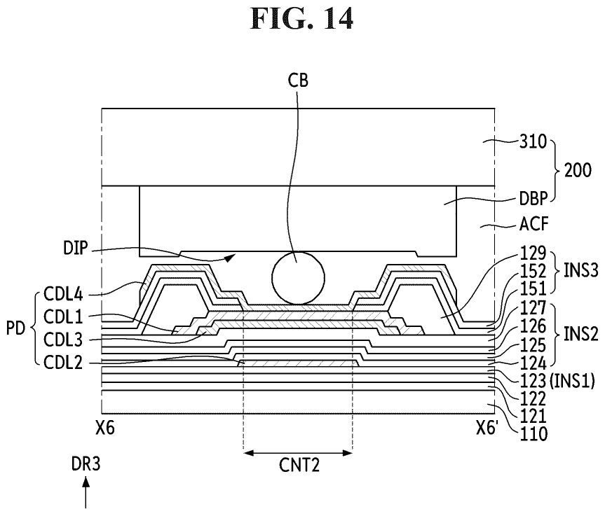

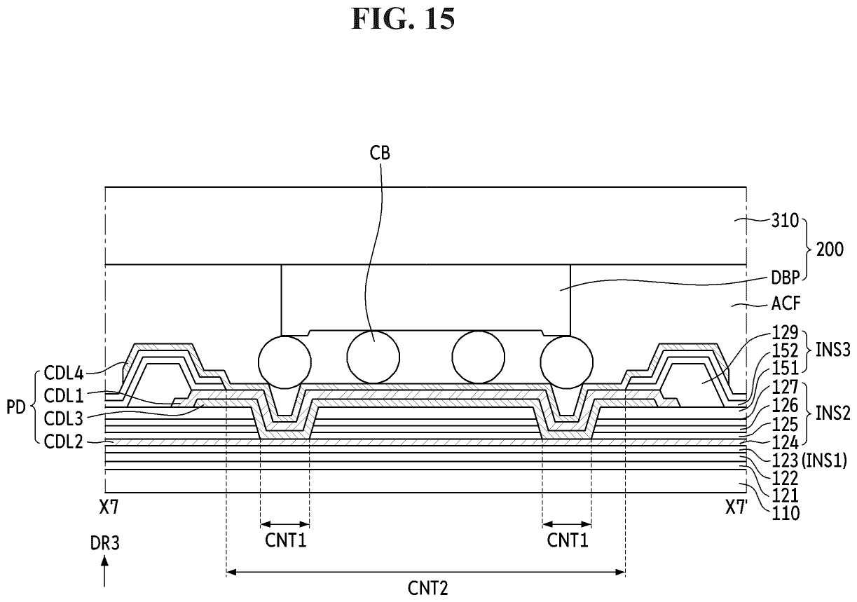

FIG. 12 is a plan view illustrating a pad area of the display device according to one or more embodiments of the present disclosure. FIGS. 13 to 15 are cross-sectional views illustrating pad areas of the display panel according to one or more embodiments of the present disclosure. For example, FIG. 12 schematically illustrates a portion of the first pad area PP1 to which the driving circuit 200 is coupled, according to one or more embodiments of the present disclosure. FIG. 13 illustrates an example of a cross-section of a portion of the first pad area PP1 corresponding to line X5-X5′ in FIG. 12, according to one or more embodiments of the present disclosure. FIG. 14 illustrates an example of a cross-section of a portion of the first pad area PP1 corresponding to line X6-X6′ in FIG. 12, according to one or more embodiments of the present disclosure. FIG. 15 illustrates an example of a cross-section of a portion of the first pad area PP1 corresponding to line X7-X7′ in FIG. 12, according to one or more embodiments of the present disclosure.

Referring to FIGS. 12 to 15 in conjunction with FIGS. 5 to 8, the driving circuit 200 may be arranged on the first pad area PP1 of the display panel 100. FIGS. 13 to 15 illustrate only the driving substrate 310 and the bump DBP to describe the coupling relationship with the bump DBP, but the driving circuit 200 may be as described in FIGS. 9 to 11.

The pad PD may be coupled to the bump DBP of the driving circuit 200. An anisotropic conductive film ACF may be arranged between the pad PD and the bump DBP to couple the pad PD and the bump DBP. The anisotropic conductive film ACF may include a plurality of conductive balls CB. The conductive ball CB may contact between (e.g., may connect) the pad PD and the bump DBP through high-temperature and high-pressure compression to electrically connect the pad PD and the bump DBP.

The conductive ball CB of the anisotropic conductive film ACF may include a conductive core and an insulating layer around (e.g., surrounding) the core. During the coupling process of the driving circuit 200, as the insulating layer ruptures and the conductive core is exposed, the pad PD and the bump DBP may be electrically connected. The conductive core may be made of, for example, a gold-nickel alloy, but the present disclosure is not limited thereto. The conductive ball CB may have a size of about 2 to 2.5 μm, for example, about 2.2 μm. The conductive balls CB of the anisotropic conductive film ACF may have density of about 25 to 30K/mm², for example, about 28K/mm². The size and density of the conductive ball CB described above are examples and the present disclosure is not limited thereto.

As illustrated in FIG. 13, the bump DBP of the driving circuit 200 may be aligned and arranged on the pad PD. The dimple DIP may be arranged on one surface of the bump DBP (e.g., a lower surface facing (e.g., opposite to) the pad PD). In an area where the first contact portion CNT1 and the second contact portion CNT2 overlap, a gap between the pad PD and the bump DBP may be formed to be greater than the size of the conductive ball CB due to the step between the dimple DIP of the bump DBP and the first contact portion CNT1. Therefore, because the conductive ball CB is spaced and/or apart (e.g., spaced apart or separated) from the pad PD and/or the bump DBP and is in non-contact therewith on the first contact portion CNT1, it is difficult to electrically connect the pad PD and the bump DBP.

Referring to FIGS. 14 and 15, in an area where only the second contact portion CNT2 is arranged (e.g., an area of the second contact portion CNT2 that does not overlap the first contact portion CNT1), the gap between the bump DBP and the pad PD may be made to be smaller than the size of the conductive ball CB. As the gap between the dimple DIP of the bump DBP and the pad PD is also made to be smaller than the size of the conductive ball CB, the pad PD and the bump DBP may each be electrically connected by being in contact with the conductive ball CB.

In one or more embodiments, as an edge of the bump DBP (e.g., an area where the first contact portion CNT1 and the edge of the bump DBP overlap) is arranged to protrude more toward the pad PD than the center of the bump DBP, the gap between the bump DBP and the pad PD may be made to be smaller than the size of the conductive ball CB. For example, because the gap between the edge of the bump DBP and the pad PD is reduced even if the pad PD has a step due to the first contact portion CNT1, the bump DBP and the pad PD may be each in contact with the conductive ball CB and be electrically connected (see, e.g., the uppermost and lowermost conductive balls CB in FIG. 15).

According to one or more embodiments, the pad PD includes a plurality of first contact portions CNT1, so that the gap between the bump DBP and the pad PD may be formed to be small in an area where the first contact portions CNT1 are spaced and/or apart (e.g., spaced apart or separated) (e.g., an area where the first contact portion CNT1 and the second contact portion CNT2 do not overlap), thereby electrically connecting the bump DBP and the pad PD through the conductive ball CB. Therefore, contact defects may be improved by expanding an electrical contact area between the pad PD and the bump DBP.

According to one or more embodiments, a total area of the plurality of first contact portions CNT1 may be 2% to 45% of an area of the pad PD (e.g., an area of the fourth conductive layer CDL4 exposed above the third insulating layer INS3). When the total area of the plurality of first contact portions CNT1 is 2% or more of the area of the pad PD, line resistance may be lowered by reducing contact resistance between the second conductive layer CDL2 and the third conductive layer CDL3 in the first contact portion CNT1. In one or more embodiments, if (e.g., when) the total area of the plurality of first contact portions CNT1 is 45% or less of the area of the pad PD, contact defects may be improved by reducing the area of the first contact portion CNT1 to increase an effective contact area where the bump DBP and the pad PD may be in contact with the conductive ball CB.

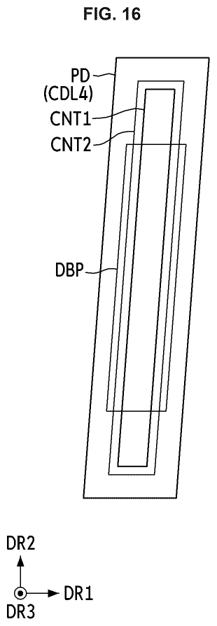

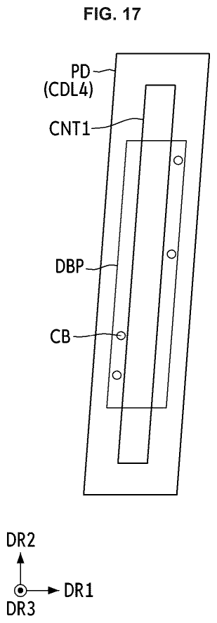

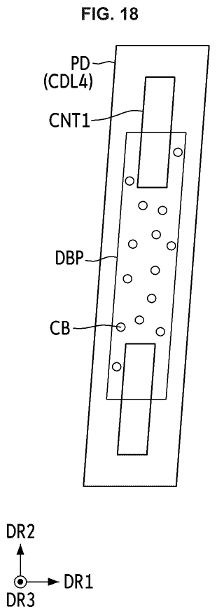

Table 1 shows the results of pad line resistance and reliability test after coupling the pad and the driving circuit according to the structure of the pad. In Table 1, the comparative example forms a pad having the structures illustrated in FIG. 16, and the embodiment illustrates a pad having the structures illustrated in FIGS. 12 to 15. FIG. 16 is a plan view illustrating a first pad area of a display panel according to a comparative example. For example, FIG. 16 illustrates a pad PD having one first contact portion CNT1, and FIGS. 12 to 15 illustrate a pad PD having two first contact portions CNT1. FIG. 17 is a schematic view illustrating a first pad area of a display panel according to a comparative example. FIG. 18 is a schematic view illustrating a first pad area of a display panel according to one or more embodiments of the present disclosure. In addition, in Table 1, the effective contact area refers to an area where the second contact portion and the bump excluding the first contact portion may be substantially in contact with each other through the conductive ball. The reliability test was conducted for 240 hours in an environment having a temperature of 85° C. and a humidity of 85%.

TABLE 1

| | | Comparative | | |
|---|---|---|---|---|
| | | Example | Embodiment | |
| Contact Area | Total Area of First | 339 μm² | 147 | μm² |
| | Contact Hole | | | |
| | Effective Contact | 800 μm² | 992.1 | μm² |

| | | | |
|---|---|---|---|
| | Area | | |
| Pad Line | After | 0.64 Ω ± 0.14 | 0.76 Ω ± 0.16 |
| Resistance | Manufacturing | | |
| | Pad | | |
| | Change in | 1.70 Ω ± 0.3 | 0.23 Ω ± 0.05 |
| | Resistance After | | |
| | Reliability Test | | |

Referring to Table 1, according to the comparative example, the pad line of the display panel having one first contact portion CNT1 showed a change in resistance of about 1.70 Ω±0.3 after the reliability test. In contrast, according to the embodiment, it was confirmed that the change in resistance of the pad line of the display panel having the two first contact portions CNT1 was significantly reduced to about 0.23 Ω±0.05 after the reliability test.

In one or more embodiments, referring to FIGS. 17 and 18, in the first pad area of the display panel according to the comparative example, the number of conductive balls CB contacting the pad PD and the bump DBP was observed to be four. In contrast, in the first pad area of the display panel according to the embodiment, the number of conductive balls CB contacting the pad PD and the bump DBP was observed to be fourteen.

Through such results, it was confirmed that in the pad PD having a plurality of first contact portions CNT1 according to the embodiment, the reliability of the pad line resistance was improved, and the number of conductive balls CB contacting the pad PD and the bump DBP was also significantly increased.

Hereinafter, one or more embodiments of the present disclosure will be described with reference to other drawings.

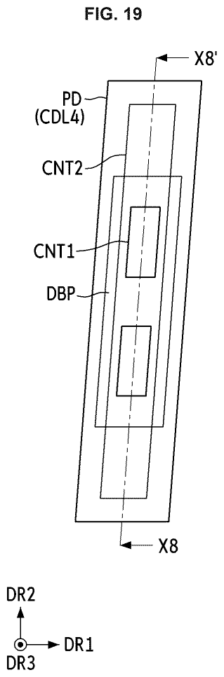

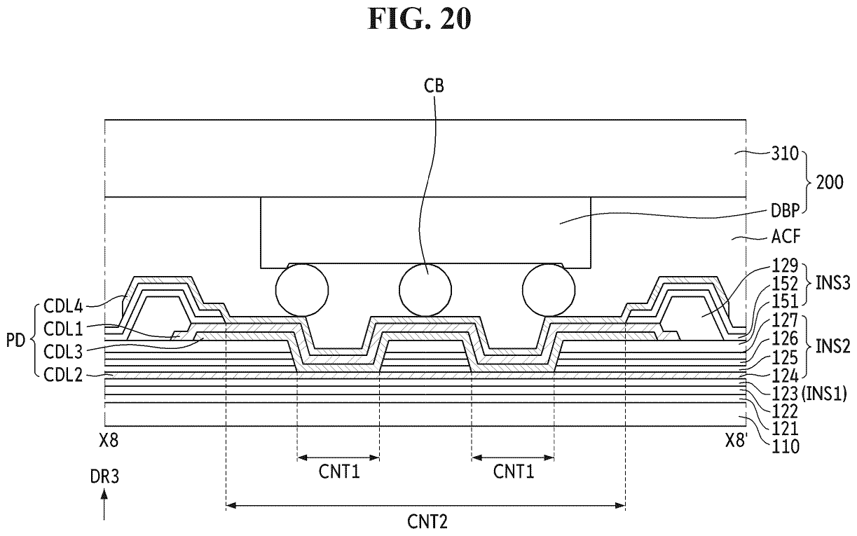

FIG. 19 is a plan view illustrating a pad of a display panel according to one or more embodiments of the present disclosure. FIG. 20 is a cross-sectional view illustrating the pad of the display panel according to one or more embodiments of the present disclosure. For example, FIG. 19 schematically illustrates one pad arranged in the first pad area of the display panel. FIG. 20 illustrates an example of a cross section of a pad corresponding to line X8-X8′ in FIG. 19, according to one or more embodiments of the present disclosure.

Referring to FIGS. 19 and 20, the present embodiment is different from one or more embodiments of FIGS. 5 to 15 described above in that all of the first contact portions CNT1 of the pad PD overlap the bump DBP. Hereinafter, descriptions overlapping the above-described embodiments may not be repeated and differences from the above-described embodiments will be described.

The pad PD of the display panel 100 according to one or more embodiments may include first contact portions CNT1 where the second conductive layer CDL2 and the third conductive layer CDL3 are in contact with each other, and a second contact portion CNT2 where the first conductive layer CDL1 and the fourth conductive layer CDL4 are in contact with each other. The driving circuit 200 may be arranged on the pad PD. The driving circuit 200 may include a bump DBP arranged on one surface of the driving substrate 310. An anisotropic conductive film ACF including a plurality of conductive balls CB may be arranged between the pad PD and the driving circuit 200 to electrically connect the pad PD and the driving circuit 200.

According to one or more embodiments, the first contact portions CNT1 may be arranged to be spaced and/or apart (e.g., spaced apart or separated) from each other, and all of the first contact portions CNT1 may overlap the bump DBP. For example, the first contact portions CNT1 may completely overlap the bump DBP. In one or more embodiments, the first contact portions CNT1 may overlap the second contact portion CNT2.

In one or more embodiments, by configuring a plurality of first contact portions CNT1 and disposing the plurality of first contact portions CNT1 to overlap the bump DBP, an effective contact area where the pad PD and the bump DBP of the driving circuit 200 may be in contact with the conductive balls CB in an area excluding the first contact portions CNT1 may be increased. Accordingly, contact defects between the pad PD and the bump DBP of the driving circuit 200 may be prevented or reduced, thereby improving pad reliability.

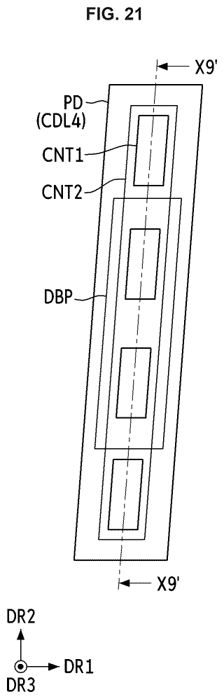

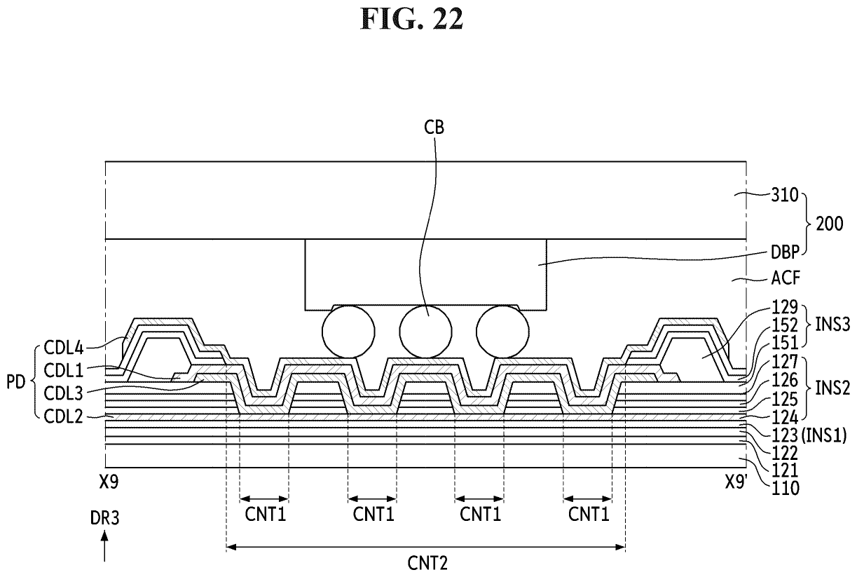

FIG. 21 is a plan view illustrating a pad of a display panel according to one or more embodiments of the present disclosure. FIG. 22 is a cross-sectional view illustrating the pad of the display panel according to one or more embodiments of the present disclosure. For example, FIG. 21 schematically illustrates one pad arranged in the first pad area of the display panel. FIG. 22 illustrates an example of a cross section of a pad corresponding to line X9-X9′ in FIG. 21, according to one or more embodiments of the present disclosure.

Referring to FIGS. 21 and 22, the present embodiment is different from the embodiments of FIGS. 5 to 15, 19, and 20 described above in that some of the first contact portions CNT1 of the pad PD overlap the bump DBP and other portions thereof do not overlap the bump DBP. Hereinafter, descriptions overlapping the above-described embodiments may be repeated and differences from the above-described embodiments will be described.

The pad PD of the display panel 100 according to one or more embodiments may include first contact portions CNT1 where the second conductive layer CDL2 and the third conductive layer CDL3 are in contact with each other, and a second contact portion CNT2 where the first conductive layer CDL1 and the fourth conductive layer CDL4 are in contact with each other. A driving circuit 200 may be arranged on the pad PD. The driving circuit 200 may include a bump DBP arranged on one surface of the driving substrate 310. An anisotropic conductive film ACF including a plurality of conductive balls CB may be arranged between the pad PD and the driving circuit 200 to electrically connect the pad PD and the driving circuit 200.

According to one or more embodiments, the first contact portions CNT1 may be arranged to be spaced and/or apart (e.g., spaced apart or separated) from each other, and some of the first contact portions CNT1 may overlap the bump DBP and others thereof may not overlap the bump DBP. For example, the first contact portions CNT1 arranged on the upper and lower sides of the drawing may not overlap the bump DBP, and the first contact portions CNT1 arranged in the center may overlap the bump DBP.

In one or more embodiments, by configuring a plurality of first contact portions CNT1 and disposing the plurality of first contact portions CNT1 so that some overlap the bump DBP and others do not overlap the bump DBP, an effective contact area where the pad PD and the bump DBP of the driving circuit 200 may be in contact with the conductive balls CB in an area excluding the first contact portions CNT1 may be increased. Accordingly, contact defects between the pad PD and the bump DBP of the driving circuit 200 may be prevented or reduced, thereby improving pad reliability.

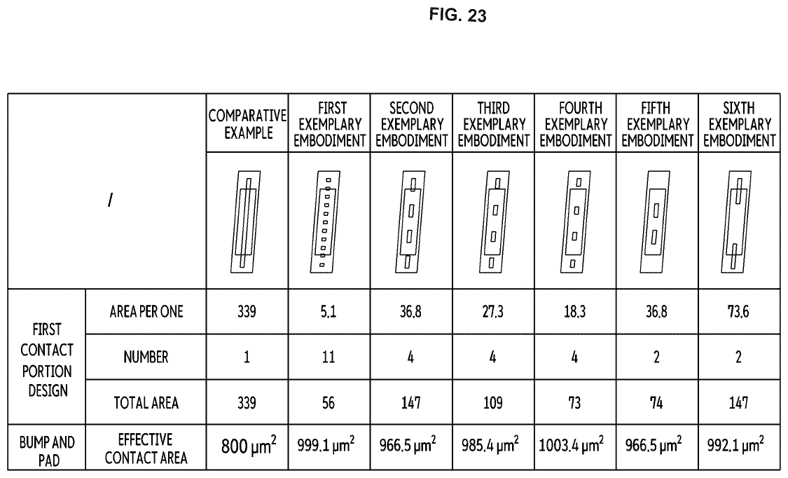

FIG. 23 is a chart illustrating the area and effective contact area of first contact portions for each pad structure according to a comparative example and embodiments of the present disclosure. For example, FIG. 23 illustrates a pad structure according to a comparative example and pad structures according to first to sixth embodiments. The pad structure according to the comparative example is as illustrated in FIG. 16 described above, the pad structure according to the first embodiment has a structure having 11 first contact portions, the pad structures according to the second to fourth embodiments have four first contact portions with different areas, the pad structure according to the fourth embodiment is as illustrated in FIG. 21 described above, the pad structure according to the fifth embodiment is as illustrated in FIG. 19 described above, and the pad structure according to the sixth embodiment is as illustrated in FIG. 5 described above.

In one or more embodiments, in the comparative example and the first to sixth embodiments in FIG. 23, the pads were manufactured by adjusting the number and area of the first contact holes while the total area of the pads was manufactured to be the same at 2,304 μm² and the area of the bump was also manufactured to be same at 1,040 μm².

Referring to FIG. 23, the pad according to the comparative example had one first contact hole and showed the effective contact area between the pad and the bump of 800 μm². The pad according to the first embodiment had 11 first contact holes and showed the effective contact area between the pad and the bump of 999.1 μm². The pad according to the second embodiment had four first contact holes and showed the effective contact area between the pad and the bump of 966.5 μm². The pad according to the third embodiment had four first contact holes and showed the effective contact area between the pad and the bump of 985.4 μm². The pad according to the fourth embodiment had four first contact holes and showed the effective contact area between the pad and the bump of 1,003.4 μm². The pad according to the fifth embodiment had two first contact holes and showed the effective contact area between the pad and the bump of 966.5 μm². The pad according to the sixth embodiment had two first contact holes and showed the effective contact area between the pad and the bump of 992.1 μm².

Through such results, it was confirmed that the pads having a plurality of first contact holes according to the first to sixth embodiments have a significantly increased effective contact area where the pad and the bump may be in contact with each through the conductive balls compared to the comparative example having one first contact hole. Accordingly, the display panel according to one or more embodiments may improve contact defects between the pad and the bump through the conductive balls and improve contact reliability of the pad.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus, device for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

1 what is claimed is:

1. A display device comprising:
a substrate having a display area and a pad area;
a first insulating layer on the pad area of the substrate;
a pad comprising a first conductive layer, a second conductive layer, a third conductive layer, and a fourth conductive layer sequentially stacked on the first insulating layer;
a second insulating layer between the first conductive layer and the second conductive layer and comprising first contact portions where the first conductive layer and the second conductive layer are in contact;
a third insulating layer between the third conductive layer and the fourth conductive layer and comprising second contact portions where the third conductive layer and the fourth conductive layer are in contact;
a driving circuit on the pad and comprising a bump; and
an anisotropic conductive film between the pad and the driving circuit and comprising a plurality of conductive balls,
wherein the first contact portions overlap the second contact portions and are spaced from each other along a longitudinal direction of the pad.

2. The display device of claim 1, wherein the second conductive layer and the third conductive layer are in contact with each other on the first contact portions, to electrically connect the first conductive layer, the second conductive layer, the third conductive layer, and the fourth conductive layer.

3. The display device of claim 1, wherein at least one of the plurality of conductive balls is on an area of the second contact portions that does not overlap the first contact portions and the at least one of the plurality of conductive balls is in contact with the pad and the bump.

4. The display device of claim 1, wherein at least one of the plurality of conductive balls overlaps the first contact portions and is not in contact with the pad or the bump.

5. The display device of claim 1, wherein a total area of the first contact portions is 2% to 45% of an area of the pad.

6. The display device of claim 5, wherein the area of the pad is an area of the fourth conductive layer.

7. The display device of claim 1, wherein a maximum distance between the pad and the bump in an area where the first contact portions and the second contact portions overlap is greater than a maximum distance between the pad and the bump in an area where the first contact portions and the second contact portions do not overlap.

8. The display device of claim 1, wherein the first contact portions at least partially overlap the bump.

9. The display device of claim 8, wherein the first contact portions completely overlap the bump.

10. The display device of claim 8, wherein at least one of the first contact portions does not overlap the bump.

11. The display device of claim 1, wherein the bump comprises a groove-shaped dimple on one surface facing the pad, and the dimple overlaps at least one of the first contact portions.

12. A display device comprising:
a substrate having a display area and a pad area;
a first insulating layer on the pad area of the substrate;
a pad comprising a first conductive layer, a second conductive layer, a third conductive layer, and a fourth conductive layer sequentially stacked on the first insulating layer;
a second insulating layer between the first conductive layer and the second conductive layer and comprising first contact portions where the first conductive layer and the second conductive layer are in contact;
a third insulating layer between the third conductive layer and the fourth conductive layer and comprising second contact portions where the third conductive layer and the fourth conductive layer are in contact;
a driving circuit on the pad and comprising a bump having a dimple on one surface facing the pad; and
an anisotropic conductive film between the pad and the driving circuit and comprising a plurality of conductive balls,
wherein in an area of the second contact portions that does not overlap the first contact portions, the pad and the bump are each in contact with the plurality of conductive balls.

13. The display device of claim 12, wherein at least one of the plurality of conductive balls overlaps the first contact portions and is not in contact with the pad or the bump.

14. The display device of claim 12, wherein a total area of the first contact portions is 2% to 45% of an area of the pad.

15. The display device of claim 14, wherein the area of the pad is an area of the fourth conductive layer.

16. The display device of claim 12, wherein the first contact portions at least partially overlap the bump.

17. The display device of claim 16, wherein the first contact portions completely overlap the bump.

18. The display device of claim 16, wherein at least one of the first contact portions does not overlap the bump.

19. The display device of claim 12, further comprising:
a transistor on the display area;
at least one planarization layer on the transistor and comprising an organic insulating material;
a connection electrode on the at least one planarization layer; and
sensor electrodes on the connection electrode,
wherein the transistor comprises an active layer between the substrate and the first insulating layer, a gate electrode on the first insulating layer, a source electrode, and a drain electrode, with at least one the source electrode or the drain electrode on the second insulating layer.

20. The display device of claim 19, wherein the first conductive layer comprises the same material as the gate electrode,
the second conductive layer comprises the same material as the source electrode or the drain electrode,
the third conductive layer comprises the same material as the connection electrode, and
the fourth conductive layer comprises the same material as the sensor electrodes.

21. An electronic device comprising:
a display device comprising:
a substrate having a display area and a pad area;
a first insulating layer on the pad area of the substrate;
a pad comprising a first conductive layer, a second conductive layer, a third conductive layer, and a fourth conductive layer sequentially stacked on the first insulating layer;
a second insulating layer between the first conductive layer and the second conductive layer and comprising first contact portions where the first conductive layer and the second conductive layer are in contact;
a third insulating layer between the third conductive layer and the fourth conductive layer and comprising second contact portions where the third conductive layer and the fourth conductive layer are in contact;
a driving circuit on the pad and comprising a bump; and
an anisotropic conductive film between the pad and the driving circuit and comprising a plurality of conductive balls,
wherein the first contact portions overlap the second contact portions and are spaced from each other along a longitudinal direction of the pad.

22. The electronic device of claim 21, wherein the second conductive layer and the third conductive layer are in contact with each other on the first contact portions, to electrically connect the first conductive layer, the second conductive layer, the third conductive layer, and the fourth conductive layer.

23. The electronic device of claim 21, wherein at least one of the plurality of conductive balls is on a portion of the second contact portions where the second contact portions do not overlap the first contact portions and is in contact with the pad and the bump.

24. The electronic device of claim 21, wherein at least one of the plurality of conductive balls overlaps the first contact portions and is not in contact with the pad or the bump.

25. The electronic device of claim 21, wherein a total area of the first contact portions is 2% to 45% of an area of the pad.

26. The electronic device of claim 25, wherein the area of the pad is an area of the fourth conductive layer.

27. The electronic device of claim 21, wherein the electronic device comprises a mobile phone, a smartphone, a tablet personal computer, a mobile communication terminal, an electronic notebook, an e-book, a portable multimedia player, a navigation system, an ultramobile personal computer, a television, a laptop, a monitor, a billboard, a smart watch, a watch phone, a glasses-type display, a head mounted display, or a car display.
